(19) United States
(12) Patent Application Publication
(10) Pub. No.: US 2026/0271554 A1
(43) Pub. Date: Sep. 10, 2026

(54) Display Substrate, Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Yuxiao LI, Beijing (CN); Fei FANG, Beijing (CN); Ling SHI, Beijing (CN); Yu WU, Beijing (CN); Haoyu LI, Beijing (CN); Changchang LIU, Beijing (CN)

(21) Appl. No.: 18/842,403

(22) PCT Filed: Oct. 19, 2023
(86) PCT No.: PCT/CN2023/125426

§ 371 Date: Aug. 29, 2024

(51) Int. Cl. H10K 59/131; H10K 59/12; H10K 59/35

(52) U.S. Cl. CPC H10K 59/131; H10K 59/1201; H10K 59/351; H10K 59/353

(57) ABSTRACT

Disclosed is a display substrate including a plurality of circuit units, a pixel drive circuit in a first circuit unit is connected with a first data signal line and a first anode, a pixel drive circuit in a second circuit unit is connected with a second data signal line and a second anode, a pixel drive circuit in a third circuit unit is connected with a third data signal line and a third anode, and a pixel drive circuit in a fourth circuit unit is connected with a fourth data signal line and a fourth anode; the first data signal line is at least partially overlapped with at least one of the second anode and the fourth anode, and/or the third data signal line is at least partially overlapped with at least one of the second anode and the fourth anode.

### CROSS-REFERENCE TO RELATED APPLICATION

The present application is a U.S. National Phase Entry of International Application No. PCT/CN2023/125426 having an international filing date of Oct. 19, 2023, contents of which should be construed as being incorporated into the present application by reference.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. The summary is not intended to limit the protection scope of claims.

In one aspect, the present disclosure provides a display substrate, including a drive structure layer disposed on a base substrate and a light emitting structure layer disposed on a side of the drive structure layer away from the base substrate, the drive structure layer includes a plurality of circuit units, the circuit unit at least include pixel drive circuits, the light emitting structure layer includes a plurality of light emitting units, the light emitting units at least include anodes; the plurality of light emitting units at least include a first light emitting unit emitting red light, a third light emitting unit emitting blue light, and a second light emitting unit and a fourth light emitting unit emitting green light, the first light emitting unit, the second light emitting unit, the third light emitting unit, and the fourth light emitting unit are periodically arranged in a first direction, the first light emitting unit and the third light emitting unit are alternately arranged in a second direction, the second light emitting unit and the fourth light emitting unit are alternately arranged in the second direction, the first direction and the second direction intersect; the first light emitting unit at least includes a first anode, the second light emitting unit at least includes a second anode, the third light emitting unit at least includes a third anode, and the fourth light emitting unit at least includes a fourth anode; the plurality of circuit units at least include a first circuit unit, a second circuit unit, a third circuit unit, and a fourth circuit unit, a pixel drive circuit in the first circuit unit is connected with the first anode, a pixel drive circuit in the second circuit unit is connected with the second anode, a pixel drive circuit in the third circuit unit is connected with the third anode, and a pixel drive circuit in the fourth circuit unit is connected with the fourth anode; the drive structure layer further includes at least a first data signal line, a second data signal line, a third data signal line, and a fourth data signal line, the first data signal line is connected with the pixel drive circuit in the first circuit unit, the second data signal line is connected with the pixel drive circuit in the second circuit unit, the third data signal line is connected with the pixel drive circuit in the third circuit unit, and the fourth data signal line is connected with the pixel drive circuit in the fourth circuit unit; an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

In an exemplary implementation mode, at least one of the first data signal line, the second data signal line, the third data signal line, and the fourth data signal line is in a shape of a character “S”.

In an exemplary implementation mode, the at least one of the first data signal line, the second data signal line, the third data signal line, and the fourth data signal line is connected with a pixel drive circuit in a following connection mode: being connected with a pixel drive circuit in a circuit unit of an Mth unit row and an Nth unit column, being connected with a pixel drive circuit in a circuit unit of an (M+1)th unit row and an (N+2)th unit column, being connected with a pixel drive circuit in a circuit unit of an (M+2)th unit row and an Nth unit column, and being connected with a pixel drive circuit in a circuit unit of an (M+3)th unit row and an (N+2)th unit column; and M and N are positive integers greater than or equal to 1.

In an exemplary implementation mode, the at least one of the first data signal line, the second data signal line, the third data signal line, and the fourth data signal line includes a first line segment, a second line segment, a third line segment, a fourth line segment, and a fifth line segment connected in sequence; the first line segment has a straight line shape or a polyline shape extending along the second direction, the first line segment is disposed in the circuit unit of the Mth unit row and the Nth unit column, and the first line segment is connected with the pixel drive circuit in the circuit unit; the second line segment has a straight line shape or a polyline shape extending along the first direction, a first end of the second line segment is connected with a second end of the first line segment, and a second end of the second line segment extends to a circuit unit of the Mth unit row and the (N+2)th unit column; the third line segment has a straight line shape or a polyline shape extending along the second direction, a first end of the third line segment is connected with the second end of the second line segment, a second end of the third line segment extends to the circuit unit of the (M+1)th unit row and the (N+2)th unit column, and the third line segment is connected with the pixel drive circuit in the circuit unit; the fourth line segment has a straight line shape or a polyline shape extending along an opposite direction of the first direction, a first end of the fourth line segment is connected with the second end of the third line segment, and a second end of the fourth line segment extends to a circuit unit of the (M+1)th unit row and the Nth unit column; and the fifth line segment has a straight line shape or a polyline shape extending along the second direction, a first end of the fifth line segment is connected with the second end of the fourth line segment, and a second end of the fifth line segment extends to the circuit unit of the (M+2)th unit row and the Nth unit column, and is connected with a first end of a first line segment in the circuit unit.

In an exemplary implementation mode, in at least one circuit unit, an orthographic projection of a third line segment of the first data signal line on the base substrate is at least partially overlapped with the orthographic projection of at least one of the second anode and the fourth anode on the base substrate, and/or, in at least one circuit unit, an orthographic projection of a third line segment of the third data signal line on the base substrate is at least partially overlapped with the orthographic projection of at least one of the second anode and the fourth anode on the base substrate.

In an exemplary implementation mode, in at least one circuit unit, an orthographic projection of a second line segment of the first data signal line on the base substrate is at least partially overlapped with an orthographic projection of the first anode on the base substrate, and/or, in at least one circuit unit, an orthographic projection of a fourth line segment of the first data signal line on the base substrate is at least partially overlapped with an orthographic projection of the third anode on the base substrate, and/or, in at least one circuit unit, an orthographic projection of a second line segment of the third data signal line on the base substrate is at least partially overlapped with an orthographic projection of the third anode on the base substrate, and/or, in at least one circuit unit, an orthographic projection of a fourth line segment of the third data signal line on the base substrate is at least partially overlapped with an orthographic projection of the first anode on the base substrate.

In an exemplary implementation mode, in at least one circuit unit, an orthographic projection of a second line segment of the second data signal line on the base substrate is at least partially overlapped with an orthographic projection of the third anode on the base substrate, and/or, in at least one circuit unit, an orthographic projection of a fourth line segment of the second data signal line on the base substrate is at least partially overlapped with an orthographic projection of the first anode on the base substrate, and/or, in at least one circuit unit, an orthographic projection of a second line segment of the fourth data signal line on the base substrate is at least partially overlapped with an orthographic projection of the first anode on the base substrate, and/or, in at least one circuit unit, an orthographic projection of a fourth line segment of the fourth data signal line on the base substrate is at least partially overlapped with an orthographic projection of the third anode on the base substrate.

In an exemplary implementation mode, at least one of the first data signal line, the second data signal line, the third data signal line, and the fourth data signal line has a dendritic shape.

In an exemplary implementation mode, a plurality of unit rows and a plurality of unit columns are formed by the plurality of circuit units, a main body portion of the at least one of the first data signal line, the second data signal line, the third data signal line, and the fourth data signal line is disposed in a plurality of circuit units of one unit column, and a connection mode of the data signal line and a pixel drive circuit is that in an odd unit row, the data signal line is connected with a pixel drive circuit in a circuit unit of the odd unit row and a next unit column, and in an even unit row, the data signal line is connected with a pixel drive circuit in a circuit unit of the even unit row and a previous unit column.

In an exemplary implementation mode, the at least one of the first data signal line, the second data signal line, the third data signal line, and the fourth data signal line includes a data trace portion and a first transfer electrode; the data trace portion has a straight line shape or a polyline shape in which a main body portion extends along the second direction, and the data trace portion is disposed in a plurality of circuit units in an even unit column; and the first transfer electrode has a straight line shape or a polyline shape extending along the first direction, the first transfer electrode is disposed in the odd unit row, a first end of the first transfer electrode is connected with the data trace portion, and a second end of the first transfer electrode extends to the circuit unit of the odd unit row and the next unit column, and is connected with the pixel drive circuit in the circuit unit.

In an exemplary implementation mode, the at least one of the first data signal line, the second data signal line, the third data signal line, and the fourth data signal line further includes a second transfer electrode and a third transfer electrode, the second transfer electrode and the third transfer electrode have a straight shape or a polyline shape extending along the first direction, the second transfer electrode and the third transfer electrode are disposed in the even unit row, a first end of the second transfer electrode is connected with the data trace portion, a second end of the second transfer electrode extends to the circuit unit of the even unit row and the previous unit column, a first end of the third transfer electrode is connected with the second in end of the second transfer electrode, and a second end of the third transfer electrode is connected with the pixel drive circuit in the circuit unit.

In an exemplary implementation mode, the at least one of the first data signal line, the second data signal line, the third data signal line, and the fourth data signal line includes a data trace portion and a first transfer electrode; the data trace portion has a straight line shape or a polyline shape in which a main body portion extends along the second direction, and the data trace portion is disposed in a plurality of circuit units in an odd unit column; and the first transfer electrode has a straight line shape or a polyline shape extending along the first direction, the first transfer electrode is disposed in the even unit row, a first end of the first transfer electrode is connected with the data trace portion, and a second end of the first transfer electrode extends to the circuit unit of the even unit row and the previous unit column, and is connected with the pixel drive circuit in the circuit unit.

In an exemplary implementation mode, the at least one of the first data signal line, the second data signal line, the third data signal line, and the fourth data signal line further includes a second transfer electrode and a third transfer electrode, the second transfer electrode and the third transfer electrode have a straight shape or a polyline shape extending along the first direction, the second transfer electrode and the third transfer electrode are disposed in the odd unit row, a first end of the second transfer electrode is connected with the data trace portion, a second end of the second transfer electrode extends to the circuit unit of the odd unit row and the next unit column, a first end of the third transfer electrode is connected with the second end of the second transfer electrode, and a second end of the third transfer electrode is connected with the pixel drive circuit in the circuit unit.

In an exemplary implementation mode, in a direction perpendicular to the base substrate, the drive structure layer includes a plurality of conductive layers, the data trace portion, the first transfer electrode, and the second transfer electrode are disposed in a same conductive layer, and the second transfer electrode and the third transfer electrode are disposed in different conductive layers.

In an exemplary implementation mode, the data trace portion, the first transfer electrode, and the second transfer electrode are of an interconnected integral structure, and the third transfer electrode is connected with the second transfer electrode through a via.

In an exemplary implementation mode, an orthographic projection of at least one third transfer electrode on the base substrate is at least partially overlapped with an orthographic projection of at least one data trace portion on the base substrate.

In an exemplary implementation mode, an orthographic projection of a data trace portion of the first data signal line on the base substrate is at least partially overlapped with the orthographic projection of the at least one of the second anode and the fourth anode on the base substrate, and/or an orthographic projection of a data trace portion of the third data signal line on the base substrate is at least partially overlapped with the orthographic projection of the at least one of the second anode and the fourth anode on the base substrate.

In another aspect, the present disclosure also provides a display apparatus, including the display substrate described above.

In yet another aspect, the present disclosure also provides a preparation method of a display substrate, including a display region and a bonding region disposed on at least one side of the display region, the method includes: forming a drive structure layer on a base substrate, wherein the drive structure layer includes a plurality of circuit units, the circuit units at least include pixel drive circuits, the plurality of circuit units include at least a first circuit unit, a second circuit unit, a third circuit unit, and a fourth circuit unit; the drive structure layer further at least includes a first data signal line, a second data signal line, a third data signal line, and a fourth data signal line, the first data signal line is connected with a pixel drive circuit in the first circuit unit, the second data signal line is connected with a pixel drive circuit in the second circuit unit, the third data signal line is connected with a pixel drive circuit in the third circuit unit, and the fourth data signal line is connected with a pixel drive circuit in the fourth circuit unit; and forming a light emitting structure layer on the drive structure layer, wherein the light emitting structure layer includes a plurality of light emitting units, the light emitting units include at least anodes; the plurality of light emitting units include at least a first light emitting unit emitting red light, a third light emitting unit emitting blue light, and a second light emitting unit and a fourth light emitting unit emitting green light, the first light emitting unit, the second light emitting unit, the third light emitting unit, and the fourth light emitting unit are periodically arranged in a first direction, the first light emitting unit and the third light emitting unit are alternately arranged in a second direction, the second light emitting unit and the fourth light emitting unit are alternately arranged in the second direction, the first direction and the second direction intersect; the first light emitting unit at least includes a first anode, the second light emitting unit at least includes a second anode, the third light emitting unit at least includes a third anode, and the fourth light emitting unit at least includes a fourth anode; and the first anode is connected with the pixel drive circuit in the first circuit unit, the second anode is connected with the pixel drive circuit in the second circuit unit, the third anode is connected with the pixel drive circuit in the third circuit unit, and the fourth anode is connected with the pixel drive circuit in the fourth circuit unit; and an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

Other aspects may be comprehended after drawings and detailed description are read and understood.

### BRIEF DESCRIPTION OF DRAWINGS

Accompany drawings are used to provide understanding of technical solutions of the present disclosure, and form a part of the specification. The accompany drawings and embodiments of the present disclosure are adopted to explain the technical solutions of the present disclosure, and do not form limitations on the technical solutions of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit.

FIGS. 5A to 5C are schematic diagrams showing a connection between a circuit unit and a light emitting unit according to an embodiment of the present disclosure.

FIG. 6 is a schematic diagram showing a connection between data signal lines in a display substrate according to an embodiment of the present disclosure.

FIG. 7 is a schematic diagram showing a positional relationship between a data signal line and an anode according to an embodiment of the present disclosure.

FIG. 8 is a schematic diagram of a display substrate after a pattern of a first semiconductor layer is formed according to the present disclosure.

FIGS. 9A and 9B are schematic diagrams of a display substrate after a pattern of a first conductive layer is formed according to the present disclosure.

FIGS. 10A and 10B are schematic diagrams of a display substrate after a pattern of a second conductive layer is formed according to the present disclosure.

FIG. 11A and FIG. 11B are schematic diagrams of a display substrate after a pattern of a second semiconductor layer is formed according to the present disclosure.

FIG. 12A and FIG. 12B are schematic diagrams of a display substrate after a pattern of a third conductive layer is formed according to the present disclosure.

FIG. 13 is a schematic diagram of a display substrate after a pattern of a sixth insulation layer is formed according to the present disclosure.

FIG. 14A and FIG. 14B are schematic diagrams of a display substrate after a pattern of a fourth conductive layer is formed according to the present disclosure.

FIG. 14C is a schematic diagram of a mesh communication structure of initial signals according to an exemplary embodiment of the present disclosure.

FIG. 15 is a schematic diagram of a display substrate after a pattern of a first planarization layer is formed according to the present disclosure.

FIG. 16A and FIG. 16B are schematic diagrams of a display substrate after a pattern of a fifth conductive layer is formed according to the present disclosure.

FIG. 16C is a schematic diagram showing a connection between a data signal line and a third connection electrode in FIG. 16A.

FIG. 17 is a schematic diagram of a display substrate after a pattern of a second planarization layer is formed according to the present disclosure;

FIG. 18A and FIG. 18B are schematic diagrams of a display substrate after a pattern of an anode conductive layer is formed according to the present disclosure.

FIG. 19 is a schematic diagram showing a connection between data signal lines in another display substrate according to an embodiment of the present disclosure.

FIG. 20 is a schematic diagram showing another positional relationship between a data signal line and an anode according to an embodiment of the present disclosure.

FIG. 21A and FIG. 21B are schematic diagrams of another display substrate after a pattern of a fifth conductive layer is formed according to the present disclosure.

FIG. 22 is a schematic diagram of another display substrate after a pattern of a second planarization layer is formed according to the present disclosure.

FIG. 23A and FIG. 23B are schematic diagrams of another display substrate after a pattern of a fifth conductive layer is formed according to the present disclosure.

FIG. 24 is a schematic diagram of another display substrate after a pattern of an anode conductive layer is formed according to the present disclosure.

Reference signs are described as follows.

11-First active layer;
12-Second active layer;
13-Third active layer;
14-Fourth active layer;
15-Fifth active layer;
16-Sixth active layer;
17-Seventh active layer;
21-First scan signal line;
22-Second scan signal line;
23-Third scan signal line;
24-Light emitting signal line;
25-First shielding line;
26-Second shielding line;
31-First initial signal line;
32-Second initial signal line;
41-First initial connection line;
42-Second initial connection line;
43-First initial connection strip;
44-Second initial connection strip;
51-First connection electrode;
52-Second connection electrode;
53-Third connection electrode;
54-Fourth connection electrode;
55-Fifth connection electrode;
56-Sixth connection electrode;
57-Seventh connection electrode;
61-Data signal line;
62-Second power supply line;
63-Anode connection electrode;
64-Eleventh connection electrode;
71-First electrode plate;
72-Second electrode plate;
73-Opening;
74-Plate electrode connection strip;
80-Data trace portion;
81-First transfer electrode;
82-Second transfer electrode;
83-Third transfer electrode;
90A-First anode;
90B-Second anode;
90C-Third anode;
90D-Fourth anode;
101-Base substrate;
102-Drive circuit layer;
103-Light emitting structure layer;
104-Encapsulation structure layer.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art may easily understand such a fact that implementation modes and contents may be transformed into various forms without departing from the purpose and scope of the present disclosure. Therefore, the present disclosure should not be explained as being limited to contents recorded in the following implementation modes only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the drawings, not to indicate or imply that referred apparatuses or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in this specification is not strictly defined, and it may be an approximate triangle, rectangle, trapezoid, pentagon, or hexagon, etc. There may be some small deformations caused by tolerance, and there may be chamfers, arc edges, deformation, etc.

In the present disclosure, “about” refers to that a boundary is not defined so strictly and numerical values within a range of process and measurement errors are allowed.

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively, wherein n, m, and o may be natural numbers. The pixel array may include a plurality of sub-pixels Pxij, i and j may be natural numbers, at least one sub-pixel Pxij may include a circuit unit and a light emitting unit, the circuit unit may include, at least, a pixel drive circuit connected with a scan signal line, a light emitting signal line, and a data signal line, respectively. The light emitting unit may include a light emitting device connected with the pixel drive circuit of the circuit unit. In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value by using a clock signal, and apply a data voltage corresponding to the grayscale value to the data signal lines D1 to Dn by taking a pixel column as a unit. The scan driver may generate scan signals to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner of sequentially transmitting a scan start signal provided in a form of an on-level pulse to a next stage circuit under control of the clock signal. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register, and generate an emission signal in a manner of sequentially transmitting an emission stop signal provided in a form of an off-level pulse to a next-stage circuit under control of the clock signal. In an exemplary implementation mode, the pixel array may be disposed on the display substrate.

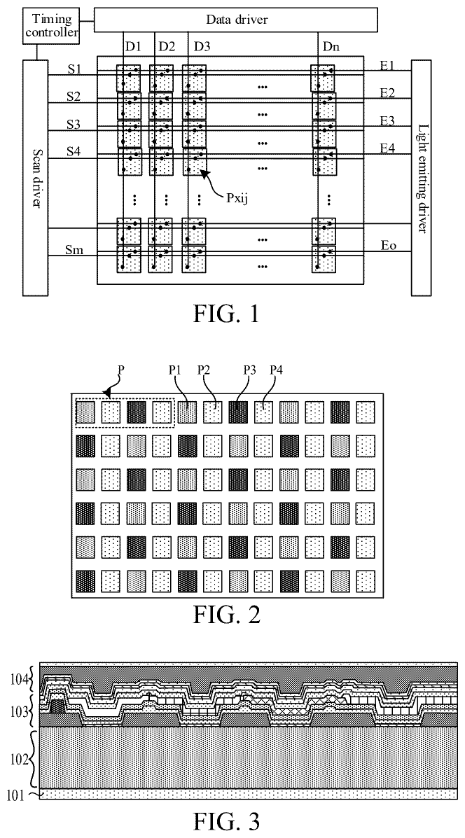

FIG. 2 is a schematic diagram of a planar structure of a display substrate. As shown in FIG. 2, a display region may include multiple pixel units P arranged in a matrix manner. At least one pixel unit P may include a first sub-pixel P1 emitting light of a first color, a second sub-pixel P2 emitting light of a second color, a third sub-pixel P3 emitting light of a third color and a fourth sub-pixel P4 emitting light of a fourth color. Each sub-pixel may include a circuit unit and a light emitting unit. The circuit unit may at least include a pixel drive circuit, the pixel drive circuit is connected with a scan signal line, a light emitting signal line, a data signal line, and a first power supply line respectively, and the pixel drive circuit is configured to receive a data voltage transmitted by the data signal line and output a corresponding current to the light emitting unit under control of the scan signal line and the light emitting signal line. A light emitting unit in each sub-pixel is connected with a pixel drive circuit of the sub-pixel where the light emitting unit is located, and is configured to emit light with corresponding brightness in response to a current output by the pixel drive circuit of the sub-pixel where the light emitting unit is located.

In an exemplary implementation mode, the first sub-pixel P1 may be a red (R) sub-pixel emitting red light, the second sub-pixel P2 may be a first green (G1) sub-pixel emitting green light, the third sub-pixel P3 may be a blue (B) sub-pixel emitting blue light, and the fourth sub-pixel P4 may be a second green (G2) sub-pixel emitting green light. In an exemplary implementation mode, a sub-pixel may be in a shape of a rectangle, a diamond, a pentagon, or a hexagon. The four sub-pixels may be arranged in an RGBG arrangement. In some other exemplary implementation modes, the four sub-pixels may be arranged side by side horizontally, side by side vertically, or in a manner to form a square, which is not limited in the present disclosure.

In an exemplary implementation mode, a pixel unit may include three sub-pixels, and the three sub-pixels may be arranged side by side horizontally, side by side vertically, or in a manner to form a triangle, which is not limited here in the present disclosure.

FIG. 3 is a schematic diagram of a sectional structure of a display substrate, which illustrates a structure of four sub-pixels. As shown in FIG. 3, on a plane perpendicular to the display substrate, the display substrate may include a drive circuit layer 102 disposed on a base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 may include a plurality of circuit units each of which may include at least a pixel drive circuit. The light emitting structure layer 103 may include multiple light emitting units, each light emitting unit may at least include a light emitting device, and the light emitting device may at least include an anode, an organic emitting layer, and a cathode. The anode is connected with the pixel drive circuit. The organic emitting layer is connected with the anode and cathode, respectively. The organic emitting layer emits light of a corresponding color under drive of the anode and the cathode. The encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material, which may ensure that external water vapor cannot enter the light emitting structure layer 103.

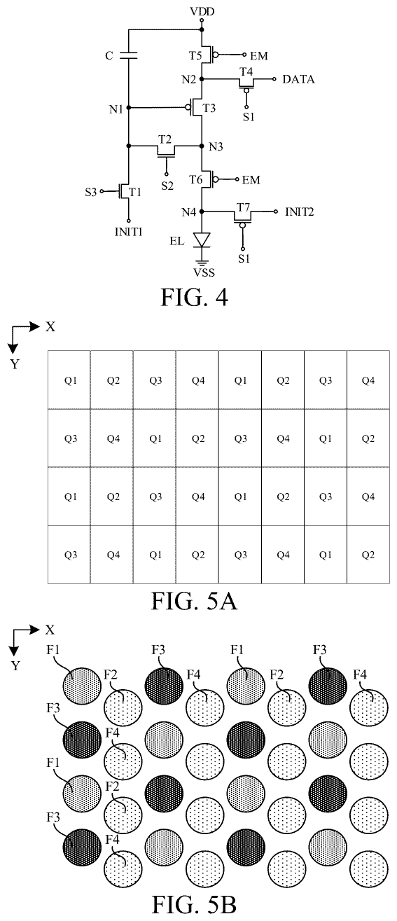

In an exemplary implementation mode, the pixel drive circuit may have a structure of 3T1C, 4T1C, 5T1C, 5T2C, 6T1C, 7T1C, or 8T1C. FIG. 4 is an equivalent circuit diagram of a pixel drive circuit. As shown in FIG. 4, the pixel drive circuit may include seven transistors (a first transistor T1 to a seventh transistor T7) and one storage capacitor C, and the pixel drive circuit is connected with eight signal lines (a first scan signal line S1, a second scan signal line S2, a third scan signal line S3, a light emitting signal line EM, a first initial signal line INIT1, a second initial signal line INIT2, a data signal line DATA, and a first power supply line VDD), respectively.

In an exemplary implementation mode, the pixel drive circuit may include a first node N1, a second node N2, a third node N3, and a fourth node N4. The first node N1 is connected with a second electrode of the first transistor T1, a first electrode of the second transistor T2, a gate electrode of the third transistor T3, and a first terminal of the storage capacitor C, respectively, the second node N2 is connected with a first electrode of the third transistor T3, a second electrode of the fourth transistor T4, and a second electrode of the fifth transistor T5, respectively, the third node N3 is connected with a second electrode of the second transistor T2, a second electrode of the third transistor T3, and a first electrode of the sixth transistor T6, respectively, and the fourth node N4 is connected with a second electrode of the sixth transistor T6 and a second electrode of the seventh transistor T7, respectively.

In an exemplary implementation mode, the first terminal of the storage capacitor C is connected with the first node N1, and a second terminal of the storage capacitor C is connected with the first power supply line VDD.

In an exemplary implementation mode, the first transistor T1 may be referred to as a first initialization transistor, a gate electrode of the first transistor T1 is connected with the third scan signal line S3, a first electrode of the first transistor T1 is connected with the first initial signal line INIT1, and the second electrode of the first transistor T1 is connected with the first node N1.

In an exemplary implementation mode, the second transistor T2 may be referred to as a compensation transistor, a gate electrode of the second transistor T2 is connected with the second scan signal line S2, the first electrode of the second transistor T2 is connected with the first node N1, and the second electrode of the second transistor T2 is connected with the third node N3.

In an exemplary implementation mode, the third transistor T3 may be referred to as a drive transistor, the gate electrode of the third transistor T3 is connected with the first node N1, the first electrode of the third transistor T3 is connected with the second node N2, and the second electrode of the third transistor T3 is connected with the third node N3.

In an exemplary implementation mode, the fourth transistor T4 may be referred to as a data writing transistor, a gate electrode of the fourth transistor T4 is connected with the first scan signal line S1, a first electrode of the fourth transistor T4 is connected with the data signal line DATA, and the second electrode of the fourth transistor T4 is connected with the second node N2.

In an exemplary implementation mode, the fifth transistor T5 may be referred to as a first light emitting control transistor, a gate electrode of the fifth transistor T5 is connected with the light emitting signal line EM, a first electrode of the fifth transistor T5 is connected with the first power supply line VDD, and the second electrode of the fifth transistor T5 is connected with the second node N2.

In an exemplary implementation mode, the sixth transistor T6 may be referred to as a second light emitting control transistor, a gate electrode of the sixth transistor T6 is connected with the light emitting signal line EM, the first electrode of the sixth transistor T6 is connected with the third node N3, and the second electrode of the sixth transistor T6 is connected with the fourth node N4.

In an exemplary implementation mode, the seven transistor T7 may be referred to as a second initialization transistor, a gate electrode of the seven transistor T7 is connected with the first scan signal line S1, a first electrode of the first transistor T7 is connected with the second initial signal line INIT2, and the second electrode of the seven transistor T7 is connected with the fourth node N4.

In an exemplary implementation mode, a first electrode of a light emitting device EL is connected with the fourth node N4, and a second electrode of the light emitting device EL is connected with the second power supply line VSS. The light emitting device EL may be an OLED including a first electrode (anode), an organic emitting layer, and a second electrode (cathode), which are stacked, or may be a QLED including a first electrode (anode), a quantum dot emitting layer, and a second electrode (cathode), which are stacked.

In an exemplary implementation mode, a signal of the first power supply line VDD is a high-level signal continuously provided, and a signal of the second power supply line VSS is a low-level signal continuously provided.

In an exemplary implementation mode, the first transistor T1 to the seventh transistor T7 may be P-type transistors or N-type transistors. In some possible implementation modes, the first transistor T1 to the seventh transistor T7 may include a P-type transistor and an N-type transistor.

In an exemplary implementation mode, for the first transistor T1 to the seventh transistor T7, low temperature poly silicon transistors may be adopted, or oxide transistors may be adopted, or a low temperature poly silicon transistor and a metal oxide transistor may be adopted. Low Temperature Poly Silicon (LTPS for short) is adopted for an active layer of a low temperature polysilicon transistor and an oxide semiconductor (Oxide) is adopted for an active layer of a metal oxide transistor. A Low temperature poly silicon film transistor has advantages such as a high migration rate and fast charging, and an oxide film transistor has advantages such as a low leakage current. The low temperature poly silicon film transistor and the oxide film transistor are integrated on one display substrate to form a Low Temperature Polycrystalline Oxide (LTPO for short) display substrate, so that advantages of both the low temperature poly silicon film transistor and the oxide film transistor may be utilized, low-frequency drive may be achieved, power consumption may be decreased, and display quality may be improved.

In an exemplary implementation mode, the first transistor T1 and the second transistor T2 may be N-type transistors of oxides, and the third transistor T3 to the seventh transistor T7 may be P-type transistors of low temperature poly silicon.

An exemplary embodiment of the present disclosure provides a display substrate. In an exemplary implementation mode, on a plane perpendicular to the display substrate, the display substrate may at least include a drive structure layer disposed on a base substrate and a light emitting structure layer disposed at a side of the drive structure layer away from the base substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected with the pixel drive circuit. The light emitting structure layer may include a plurality of light emitting units, and at least one of the light emitting units may include a light emitting device connected with a pixel drive circuit of the corresponding circuit unit. The light emitting device is configured to emit light with corresponding brightness in response to a current output by the pixel drive circuit connected with the light emitting device.

In an exemplary implementation mode, the circuit units mentioned in the present disclosure refer to regions divided according to pixel drive circuits, and the light emitting units mentioned in the present disclosure refer to regions divided according to light emitting devices. In an exemplary implementation mode, a position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

An exemplary embodiment of the present disclosure provides a display substrate, including a drive structure layer arranged on a base substrate and a light emitting structure layer arranged at a side of the drive structure layer away from the base substrate, the drive structure layer includes a plurality of circuit units, a circuit unit at least includes a pixel drive circuit, the light emitting structure layer includes a plurality of light emitting units, a light emitting unit at least include an anode; the plurality of light emitting units at least include a first light emitting unit emitting red light, a third light emitting unit emitting blue light, and a second light emitting unit and a fourth light emitting unit emitting green light. In a first direction, the first light emitting unit, the second light emitting unit, the third light emitting unit, and the fourth light emitting unit are periodically arranged, in a second direction, the first light emitting unit and the third light emitting unit are alternately arranged and the second light emitting unit and the fourth light emitting unit are alternately arranged, the first direction and the second direction intersect; the first light emitting unit at least includes a first anode, the second light emitting unit at least includes a second anode, the third light emitting unit at least includes a third anode, and the fourth light emitting unit at least includes a fourth anode; the plurality of circuit units at least include a first circuit unit, a second circuit unit, a third circuit unit, and a fourth circuit unit, a pixel drive circuit in the first circuit unit is connected with the first anode, a pixel drive circuit in the second circuit unit is connected with the second anode, a pixel drive circuit in the third circuit unit is connected with the third anode, and a pixel drive circuit in the fourth circuit unit is connected with the fourth anode; the drive structure layer further includes at least a first data signal line, a second data signal line, a third data signal line, and a fourth data signal line, the first data signal line is connected with the pixel drive circuit in the first circuit unit, the second data signal line is connected with the pixel drive circuit in the second circuit unit, the third data signal line is connected with the pixel drive circuit in the third circuit unit, and the fourth data signal line is connected with the pixel drive circuit in the fourth circuit unit; an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

In an exemplary implementation mode, at least one signal line of the first data signal line, the second data signal line, the third data signal line, and the fourth data signal line is in a shape of a character “S”.

In an exemplary implementation mode, a connection mode of the at least one signal line of the first data signal line, the second data signal line, the third data signal line, and the fourth data signal line and a pixel drive circuit is as follows: the at least one signal line is connected with a pixel drive circuit in a circuit unit of an Mth unit row and an Nth unit column, the at least one signal line is connected with a pixel drive circuit in a circuit unit of an (M+1)th unit row and an (N+2)th unit column, the at least one signal line is connected with a pixel drive circuit in a circuit unit of an (M+2)th unit row and the Nth unit column, and the at least one signal line is connected with a pixel drive circuit in a circuit unit of an (M+3)th unit row and the (N+2)th unit column; wherein M and N are positive integers greater than or equal to 1.

In an exemplary implementation mode, at least one signal line of the first data signal line, the second data signal line, the third data signal line, and the fourth data signal line has a dendritic shape.

In an exemplary implementation mode, a plurality of unit rows and a plurality of unit columns are formed by the plurality of circuit units, a main body portion of the at least one signal line of the first data signal line, the second data signal line, the third data signal line, and the fourth data signal line is arranged in a plurality of circuit units of one unit column, and a connection mode of the data signal line and a pixel drive circuit is that in an odd unit row, the data signal line is connected with a pixel drive circuit in a circuit unit of the odd unit row and a next unit column, and in an even unit row, the data signal line is connected with a pixel drive circuit in a circuit unit of the even unit row and a previous unit column.

FIG. 5A is a schematic diagram of an arrangement of circuit units according to an exemplary embodiment of the present disclosure, FIG. 5B is a schematic diagram of an arrangement of light emitting units according to an exemplary embodiment of the present disclosure, and FIG. 5C is a schematic diagram of a connection between a circuit unit and a light emitting unit according to an exemplary embodiment of the present disclosure. As shown in FIGS. 5A, 5B, and 5C, on a plane parallel to the display substrate, a drive structure layer may include a plurality of circuit units, the plurality of circuit units may constitute a plurality of unit rows and a plurality of unit columns, a unit row may include a plurality of circuit units sequentially disposed in along a first direction X, a unit column may include a plurality of circuit units sequentially disposed in a second direction Y, and a circuit unit may include at least a pixel drive circuit. A light emitting structure layer may include a plurality of light emitting units, the plurality of light emitting units may constitute a plurality of light emitting rows and a plurality of light emitting columns, a light emitting row may include a plurality of light emitting units sequentially disposed along the first direction X, a light emitting column may include a plurality of light emitting units sequentially disposed along the second direction Y, and a light emitting unit may include at least a light emitting device. In an exemplary implementation mode, the first direction X intersects with the second direction Y. In an exemplary implementation mode, directions of the unit row and the light emitting row may be the first direction X and directions of the unit column and the light emitting column may be the second direction Y.

In an exemplary implementation mode, the plurality of circuit units may include a first circuit unit Q1, a second circuit unit Q2, and a third circuit unit Q3, and a fourth circuit unit Q4. In the first direction X (unit row direction), the first circuit unit Q1, the second circuit unit Q2, the third circuit unit Q3, and the fourth circuit unit Q4 may be periodically arranged in the first direction X. In the second direction Y (unit column direction), the first circuit unit Q1 and the third circuit unit Q3 are alternately arranged in the second direction Y, the second circuit unit Q2 and the fourth circuit unit Q4 are alternately arranged in the second direction Y, and corresponding circuit units of an odd unit row and an even unit row are arranged in a staggered manner.

In an exemplary implementation mode, the plurality of light emitting units may include a first light emitting unit F1, a second light emitting unit F2, a third light emitting unit F3, and a fourth light emitting unit F4. In the first direction X (light emitting row direction), the first light emitting unit F1, the second light emitting unit F2, the third light emitting unit F3, and the fourth light emitting unit F4 may be periodically arranged in the first direction X. In the second direction Y (light emitting column direction), the first light emitting unit F1 and the third light emitting unit F3 are alternately arranged in the second direction Y, the second light emitting unit F2 and the fourth light emitting unit F4 are alternately arranged in the second direction Y, and corresponding light emitting units of an odd light emitting row and an even light emitting row are arranged in a staggered manner.

In an exemplary implementation mode, the first light emitting unit F1 may be a light emitting unit (which may be referred to as a red light emitting unit) emitting red light, and the first light emitting unit F1 may include at least a first anode. The second light emitting unit F2 may be a light emitting unit (which may be referred to as a first green light emitting unit) emitting green light, and the second light emitting unit F2 may include at least a second anode. The third light emitting unit F3 may be a light emitting unit (which may be referred to as a blue light emitting unit) emitting blue light, and the third light emitting unit F3 may include at least a third anode. The fourth light emitting unit F4 may be a light emitting unit (which may be referred to as a second green light emitting unit) emitting green light, and the fourth light emitting unit F4 may include at least a fourth anode.

In an exemplary implementation mode, a position of an orthographic projection of a pixel drive circuit in the first circuit unit Q1 on the base substrate corresponds substantially to a position of an orthographic projection of the first anode in the first light emitting unit F1 on the base substrate, and the pixel drive circuit in the first circuit unit Q1 is connected with the first anode. A position of an orthographic projection of a pixel drive circuit in the second circuit unit Q2 on the base substrate corresponds substantially to a position of an orthographic projection of the second anode in the second light emitting unit F2 on the base substrate, and the pixel drive circuit in the second circuit unit Q2 is connected with the second anode. A position of an orthographic projection of a pixel drive circuit in the third circuit unit Q3 on the base substrate corresponds substantially to a position of an orthographic projection of the third anode in the third light emitting unit F3 on the base substrate, and the pixel drive circuit in the third circuit unit Q3 is connected with the third anode. A position of an orthographic projection of a pixel drive circuit in the fourth circuit unit Q4 on the base substrate corresponds substantially to a position of an orthographic projection of the fourth anode in the fourth light emitting unit F4 on the base substrate, and the pixel drive circuit in the fourth circuit unit Q4 is connected with the fourth anode.

In an exemplary implementation mode, a shape of the circuit unit may include any one or more of following: a triangle, a rectangle, a rhombus, a pentagon, and a hexagon, and a shape of the light emitting unit may include any one or more of following: a triangle, a rectangle, a rhombus, a pentagon, and a hexagon.

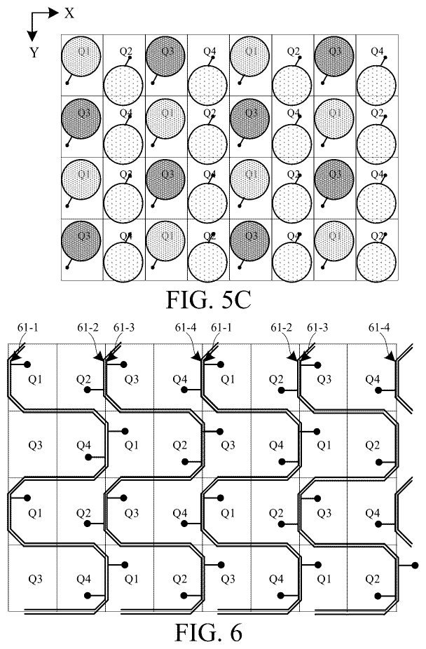

FIG. 6 is a schematic diagram showing a connection between data signal lines in a display substrate according to an exemplary embodiment of the present disclosure. As shown in FIG. 6, in an exemplary implementation mode, the drive structure layer may further include a plurality of data signal lines connected with pixel drive circuits in the plurality of circuit units, and a data signal line is configured to provide a data signal to a pixel drive circuit connected with the data signal line. In the exemplary embodiment according to the present disclosure, the plurality of data signal lines may include at least a first data signal line 61-1, a second data signal line 61-2, a third data signal line 61-3, and a fourth data signal line 61-4, the first data signal line 61-1 is connected with a pixel drive circuit of the first circuit unit Q1, the second data signal line 61-2 is connected with a pixel drive circuit of the second circuit unit Q2, the third data signal line 61-3 is connected with a pixel drive circuit of the third circuit unit Q3, and the fourth data signal line 61-4 is connected with a pixel drive circuit of the fourth circuit unit Q4.

In an exemplary implementation mode, since the pixel drive circuit of the first circuit unit Q1 is connected only with the first anode in the first light emitting unit that emits red light, the pixel drive circuit of the first circuit unit Q1 is a pixel drive circuit that drives the red light, and since the first data signal line 61-1 is connected with the pixel drive circuit of the first circuit unit Q1, the first data signal line 61-1 is a data signal line that only transmits a red image data signal. Since the pixel drive circuit of the second circuit unit Q2 is connected only with the second anode in the second light emitting unit that emits green light, the pixel drive circuit of the second circuit unit Q2 is a pixel drive circuit that drives the green light, and since the second data signal line 61-2 is connected with the pixel drive circuit of the second circuit unit Q2, the second data signal line 61-2 is a data signal line that only transmits a green image data signal. Since the pixel drive circuit of the third circuit unit Q3 is connected only with the third anode in the third light emitting unit that emits blue light, the pixel drive circuit of the third circuit unit Q3 is a pixel drive circuit that drives the blue light, and since the third data signal line 61-3 is connected with the pixel drive circuit of the third circuit unit Q3, the third data signal line 61-3 is a data signal line that only transmits a blue image data signal. Since the pixel drive circuit of the fourth circuit unit Q4 is connected only with the fourth anode in the fourth light emitting unit that emits green light, the pixel drive circuit of the fourth circuit unit Q4 is a pixel drive circuit that drives the green light, and since the fourth data signal line 61-4 is connected with the pixel drive circuit of the fourth circuit unit Q4, the fourth data signal line 61-4 is a data signal line that only transmits a green image data signal. In the present disclosure, by setting a same data signal line to be connected with pixel driving circuits that drive a same color, power consumption for displaying a pure red image and displaying a pure blue image may be effectively reduced without changing an existing drive logic.

In some possible implementation modes, since both the second light emitting unit and the fourth light emitting unit emit green light and both the second data signal line 61-2 and the fourth data signal line 61-4 transmit green image data signals, the pixel drive circuit of the second circuit unit Q2 may be connected with the fourth anode, the pixel drive circuit of the fourth circuit unit Q4 may be connected with the second anode, the second data signal line 61-2 may be connected with the pixel drive circuit of the fourth circuit unit Q4, and the fourth data signal line 61-4 may be connected with the pixel drive circuit of the second circuit unit Q2.

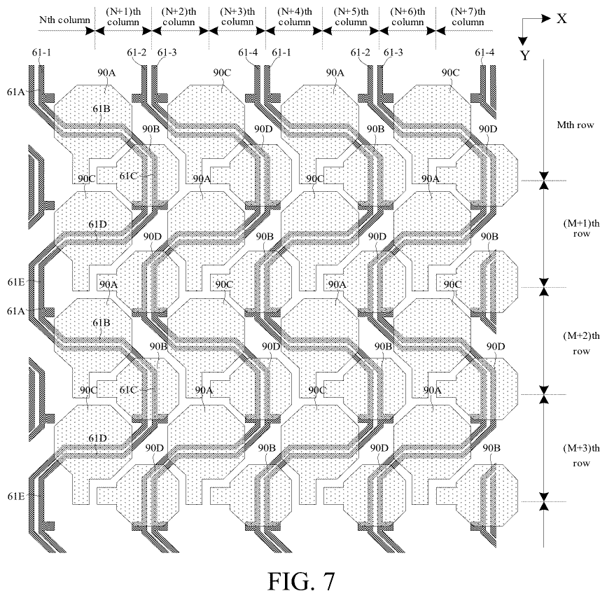

FIG. 7 is a schematic diagram showing a positional relationship between a data signal line and an anode according to an exemplary embodiment of the present disclosure. In an exemplary implementation mode, the first data signal line 61-1, the second data signal line 61-2, the third data signal line 61-3, and the fourth data signal line 61-4 may be in a shape of a character “S”, main body portions of the plurality of data signal lines extend along the second direction Y, and at least one data signal line may be provided across a plurality of unit columns and be connected with pixel drive circuits driving a same color.

As shown in FIGS. 6 and 7, a corresponding relationship between a circuit unit and a light emitting unit is the same as that shown in FIG. 5A to FIG. 5C. In an Mth unit row and an (M+2)th unit row, circuit units of an Nth unit column and an (N+4)th unit column are first circuit units corresponding to first light emitting units (red light emitting units), circuit units of an (N+1)th unit column and an (N+5)th unit column are second circuit units corresponding to second light emitting units (green light emitting units), circuit units of an (N+2)th unit column and an (N+6)th unit column are third circuit units corresponding to third light emitting units (blue light emitting units), and circuit units of an (N+3)th unit column and an (N+7)th unit column are fourth circuit units corresponding to fourth light emitting units (green light emitting units). In an (M+1)th unit row and an (M+3)th unit row, circuit units of the Nth unit column and the (N+4)th unit column are third circuit units corresponding to third light emitting units (blue light emitting units), circuit units of the (N+1)th unit column and the (N+5)th unit column are fourth circuit units corresponding to fourth light emitting units (green light emitting units), circuit units of the (N+2)th unit column and the (N+6)th unit column are first circuit units corresponding to first light emitting units (red light emitting units), and circuit units of the (N+3)th unit column and the (N+7)th unit column are second circuit units corresponding to second light emitting units (green light emitting units).

In an exemplary implementation mode, a connection mode between a data signal line and a pixel drive circuit is as follows.

For a first data signal line 61-1 transmitting a data signal of a red image, the first data signal line 61-1 extends to a first circuit unit of the Mth unit row and the Nth unit column, and is connected with a pixel drive circuit in the first circuit unit. Then the first data signal line 61-1 extends to a first circuit unit of the (M+1)th unit row and the (N+2)th unit column, and is connected with a pixel drive circuit in the first circuit unit. Then the first data signal line 61-1 extends to a first circuit unit of the (M+2)th unit row and the Nth unit column, and is connected with a pixel drive circuit in the first circuit unit. Then the first data signal line 61-1 extends to a first circuit unit of the (M+3)th unit row and the (N+2)th unit column, and is connected with a pixel drive circuit in the first circuit unit. Since each of pixel drive circuits of a plurality of first circuit units is connected with a first anode 90A in a red light emitting unit, a connection between the first data signal line 61-1 and a pixel drive circuit driving a red light emitting unit is achieved.

For a second data signal line 61-2 transmitting a data signal of a green image, the second data signal line 61-2 extends to a second circuit unit of the Mth unit row and the (N+1)th unit column, and is connected with a pixel drive circuit in the second circuit unit. Then the second data signal line 61-2 extends to a second circuit unit of the (M+1)th unit row and the (N+3)th unit column, and is connected with a pixel drive circuit in the second circuit unit. Then the second data signal line 61-2 extends to a second circuit unit of the (M+2)th unit row and the (N+1)th unit column, and is connected with a pixel drive circuit in the second circuit unit. Then the second data signal line 61-2 extends to a second circuit unit of the (M+3)th unit row and the (N+3)th unit column, and is connected with a pixel drive circuit in the second circuit unit. Since each of pixel drive circuits of a plurality of second circuit units is connected with a second anode 90B in a green light emitting unit, a connection between the second data signal line 61-2 and a pixel drive circuit driving a green light emitting units is achieved.

For a third data signal line 61-3 transmitting a data signal of a blue image, the third data signal line 61-3 extends to a third circuit unit of the Mth unit row and the (N+2)th unit column, and is connected with a pixel drive circuit in the third circuit unit. Then the third data signal line 61-3 extends to a third circuit unit of the (M+1)th unit row and the (N+4)th unit column, and is connected with a pixel drive circuit in the third circuit unit. Then the third data signal line 61-3 extends to a third circuit unit of the (M+2)th unit row and the (N+2)th unit column, and is connected with a pixel drive circuit in the third circuit unit. Then the third data signal line 61-3 extends to a third circuit unit of the (M+3)th unit row and the (N+4)th unit column, and is connected with a pixel drive circuit in the third circuit unit. Since each of pixel drive circuits of a plurality of third circuit units is connected with a third anode 90C in a blue light emitting unit, a connection between the third data signal line 61-3 and a pixel drive circuit driving a blue light emitting unit is achieved.

For a fourth data signal line 61-4 transmitting a data signal of a green image, the fourth data signal line 61-4 extends to a fourth circuit unit of the Mth unit row and the (N+3)th unit column, and is connected with a pixel drive circuit in the fourth circuit unit. Then the fourth data signal line 61-4 extends to a fourth circuit unit of the (M+1)th unit row and the (N+5)th unit column, and is connected with a pixel drive circuit in the fourth circuit unit. Then the fourth data signal line 61-4 extends to a fourth circuit unit of the (M+2)th unit row and the (N+3)th unit column, and is connected with a pixel drive circuit in the fourth circuit unit. Then the fourth data signal line 61-4 extends to a fourth circuit unit of the (M+3)th unit row and the (N+5)th unit column, and is connected with a pixel drive circuit in the fourth circuit unit. Since each of pixel drive circuits of a plurality of fourth circuit units is connected with a fourth anode 90D in a green light emitting unit, a connection between the fourth data signal line 61-4 and a pixel drive circuit driving a green light emitting unit is achieved.

In an exemplary implementation mode, an orthographic projection of the first data signal line 61-1 transmitting the data signal of the red image on the base substrate is at least partially overlapped with an orthographic projection of at least one of the second anode 90B and the fourth anode 90D in the green light emitting unit on the base substrate.

In an exemplary implementation mode, an orthographic projection of the third data signal line 61-3 transmitting the data signal of the blue image on the base substrate is at least partially overlapped with an orthographic projection of at least one of the second anode 90B and the fourth anode 90D in the green light emitting unit on the base substrate.

In an exemplary implementation mode, orthographic projections of the second data signal line 61-2 and the fourth data signal line 61-4 transmitting the data signal of the green image on the base substrate are at least partially overlapped with an orthographic projection of the first anode 90A in the red light emitting unit on the base substrate, and/or orthographic projections of the second data signal line 61-2 and the fourth data signal line 61-4 transmitting the data signal of the green image on the base substrate are at least partially overlapped with an orthographic projection of the third anode 90C in the blue light emitting unit on the base substrate.

In an exemplary implementation mode, at least one of the first data signal line 61-1, the second data signal line 61-2, the third data signal line 61-3, and the fourth data signal line 61-4 includes a first line segment 61A, a second line segment 61B, a third line segment 61C, a fourth line segment 61D, and a fifth line segment 61E connected in sequence.

In an exemplary implementation mode, the first data signal line 61-1 is taken as an example. The first line segment 61A may be in a shape of a straight line or a polyline extending along the second direction Y, the first line segment 61A is provided in a circuit unit of the Mth unit row and the Nth unit column, and the first line segment 61A is connected with a pixel drive circuit in the circuit unit. The second line segment 61B may be in a shape of a straight line or a polyline extending along the first direction X, a first end of the second line segment 61B is connected with a second end of the first line segment 61A, and a second end of the second line segment 61B extends to a circuit unit of the Mth unit row and the (N+2)th unit column. The third line segment 61C may be in a shape of a straight line or a polyline extending along the second direction Y, a first end of the third line segment 61C is connected with a second end of the second line segment 61B, a second end of the third line segment 61C extends to a circuit unit of the (M+1)th unit row and the (N+2)th unit column, and the third line segment 61C is connected with a pixel drive circuit in the circuit unit. The fourth line segment 61D may be in a shape of a straight line or a polyline extending along an opposite direction of the first direction X, a first end of the fourth line segment 61D is connected with the second end of the third line segment 61C, and a second end of the fourth line segment 61D extends to a circuit unit of the (M+1)th unit row and the Nth unit column. The fifth line segment 61E may be in a shape of a straight line or a polyline extending along the second direction Y, a first end of the fifth line segment 61E is connected with the second end of the fourth line segment 61D, and a second end of the fifth line segment 61E extends to a circuit unit of the (M+2)th unit row and the Nth unit column, and is connected with the first end of the first line segment 61A in the circuit unit.

In an exemplary implementation mode, in at least one circuit unit, an orthographic projection of a third line segment 61C of the first data signal line 61-1 on the base substrate is at least partially overlapped with an orthographic projection of at least one of the second anode 90B and the fourth anode 90D on the base substrate.

In an exemplary implementation mode, in at least one circuit unit, an orthographic projection of a third line segment 61C of the third data signal line 61-3 on the base substrate is at least partially overlapped with an orthographic projection of at least one of the second anode 90B and the fourth anode 90D on the base substrate.

In an exemplary implementation mode, in at least one circuit unit, an orthographic projection of a second line segment 61B of the first data signal line 61-1 on the base substrate is at least partially overlapped with an orthographic projection of the first anode 90A on the base substrate.

In an exemplary implementation mode, in at least one circuit unit, an orthographic projection of a fourth line segment 61D of the first data signal line 61-1 on the base substrate is at least partially overlapped with an orthographic projection of the third anode 90C on the base substrate.

In an exemplary implementation mode, in at least one circuit unit, an orthographic projection of a second line segment 61B of the third data signal line 61-3 on the base substrate is at least partially overlapped with an orthographic projection of the third anode 90C on the base substrate.

In an exemplary implementation mode, in at least one circuit unit, an orthographic projection of a fourth line segment 61D of the third data signal line 61-3 on the base substrate is at least partially overlapped with an orthographic projection of the first anode 90A on the base substrate.

In an exemplary implementation mode, in at least one circuit unit, an orthographic projection of a second line segment 61B of the second data signal line 61-2 on the base substrate is at least partially overlapped with an orthographic projection of the third anode 90C on the base substrate.

In an exemplary implementation mode, in at least one circuit unit, an orthographic projection of a fourth line segment 61D of the second data signal line 61-2 on the base substrate is at least partially overlapped with an orthographic projection of the first anode 90A on the base substrate.

In an exemplary implementation mode, in at least one circuit unit, an orthographic projection of a second line segment 61B of the fourth data signal line 61-4 on the base substrate is at least partially overlapped with an orthographic projection of the first anode 90A on the base substrate.

In an exemplary implementation mode, in at least one circuit unit, an orthographic projection of a fourth line segment 61D of the fourth data signal line 61-4 on the base substrate is at least partially overlapped with an orthographic projection of the third anode 90C on the base substrate.

Exemplary description is made below through a preparation process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation mode, taking thirty-two circuit units (four unit rows and eight unit columns) as an example, a preparation process of the display substrate according to the present embodiment may include following operations. In an Mth unit row and an (M+2)th unit row, circuit units of an Nth unit column to an (N+3)th unit column and an (N+4) unit column to an (N+7)th unit column are the first circuit unit, the second circuit unit, the third circuit unit, and the fourth circuit unit, respectively; In an (M+1)th unit row and an (M+3)th unit row, circuit units of the Nth unit column to the (N+3)th unit column, and the (N+4)th unit column to the (N+7)th unit column are the third circuit unit, the fourth circuit unit, the first circuit unit, and the second circuit unit, respectively.
(1) A pattern of a first semiconductor layer is formed. In an exemplary implementation mode, forming the pattern of the first semiconductor layer may include: sequentially depositing a first insulation thin film and a first semiconductor thin film on a base substrate, patterning the first semiconductor thin film through a patterning process to form a first insulation layer disposed on the base substrate, and the pattern of the first semiconductor layer disposed on the first insulation layer, as shown in FIG. 8.

In an exemplary implementation mode, a pattern of a first semiconductor layer of each circuit unit may at least include a third active layer 13 of a third transistor T3 to a seventh active layer 17 of a seventh transistor T7, and the third active layer 13 to the seventh active layer 17 are of an interconnected integral structure.

In an exemplary implementation mode, in the second direction Y, the fourth active layer 14 may be located on a side of the third active layer 13 in the present circuit unit in an opposite direction of the second direction Y, and the fifth active layer 15, the sixth active layer 16, and the seventh active layer 17 may be located on a side of the third active layer 13 in the present circuit unit in the second direction Y.

In an exemplary implementation mode, the third active layer 13 may be in a shape of a character “2”, the fourth active layer 14, the fifth active layer 15, and the sixth active layer 16 may be in a shape of a straight line or a polyline extending along the second direction Y, and the seventh active layer 17 may be in a shape of a character “L”.

In an exemplary implementation mode, the third active layer 13 to the seventh active layer 17 may each include a first region, a second region, and a channel region located between the first region and the second region.

In an exemplary implementation mode, a first region 13-1 of the third active layer, a second region 14-2 of the fourth active layer, and a second region 15-2 of the fifth active layer may be interconnected, that is, the first region 13-1 of the third active layer may simultaneously may serve as the second region 14-2 of the fourth active layer and the second region 15-2 of the fifth active layer. A second region 13-2 of the third active layer 13 and a first region 16-1 of the sixth active layer 16 may be connected with each other, that is, the second region 13-2 of the third active layer 13 may serve as the first region 16-1 of the sixth active layer 16. A second region 16-2 of the sixth active layer 16 and a second region 17-2 of the seventh active layer 17 may be connected with each other, that is, the second region 16-2 of the sixth active layer 16 may serve as the second region 17-2 of the seventh active layer 17. A first region 14-1 of the fourth active layer, a first region 15-1 of the fifth active layer, and a first region 17-1 of the seventh active layer are separately disposed.

In an exemplary implementation mode, in one unit row, first regions 15-1 of fifth active layers in some two adjacent circuit units may be connected with each other, the fifth active layers in the two adjacent circuit units may be of an interconnected integral structure. For example, a fifth active layer 15 of the (N+1)th unit column and a fifth active layer 15 of the (N+2)th unit column may be of an interconnected integral structure. For another example, a fifth active layer 15 of the (N+3)th unit column and a fifth active layer 15 of the (N+4)th unit column may be of an interconnected integral structure. For another example, a fifth active layer 15 of the (N+5)th unit column and a fifth active layer 15 of the (N+6)th unit column may be of an interconnected integral structure. Since a first region 15-1 of a fifth active layer in each circuit unit is configured to be connected with a first power supply line formed subsequently, by forming fifth active layers of some adjacent circuit units into an interconnected integral structure, it is not only possible to reduce an occupied area of a pixel drive circuit, which is conducive to improving a resolution, but also to ensure that first electrodes of fifth transistors of the adjacent circuit units has a same potential, which is conducive to improving uniformity of a panel, avoiding poor display of the display substrate, and ensuring a display effect of the display substrate.

In an exemplary implementation mode, in a unit column, a seventh active layer 17 may be provided across two adjacent circuit units, a second region 17-2 of the seventh active layer may be located within a current circuit unit, and a first region 17-1 of the seventh active layer may be located within a circuit unit of a next unit row. For example, a first region 17-1 of a seventh active layer of the Mth unit row may be located within a circuit unit of the (M+1)th unit row. For another example, a first region 17-1 of a seventh active layer of the (M+1)th unit row may be located within a circuit unit of the (M+2)th unit row. For another example, a first region 17-1 of a seventh active layer of the (M+2)th unit row may be located in a circuit unit of the (M+3)th unit row.

In an exemplary implementation mode, first semiconductor layers of adjacent unit columns may be mirror symmetric with respect to a column dividing line, the column dividing line may be a straight line located between the adjacent unit columns and extending in the second direction Y. For example, a first semiconductor layer in the Nth unit column and a first semiconductor layer in the (N+1)th unit column may be mirror symmetric with respect to a column dividing line. For another example, the first semiconductor layer in the (N+1)th unit column and a first semiconductor layer in the (N+2)th unit column may be mirror symmetric with respect to a column dividing line. For another example, the first semiconductor layer in the (N+2)th unit column and a first semiconductor layer in the (N+3)th unit column may be mirror symmetric with respect to a column dividing line.

In an exemplary implementation mode, shapes of first semiconductor layers in a plurality of unit rows may be substantially the same.

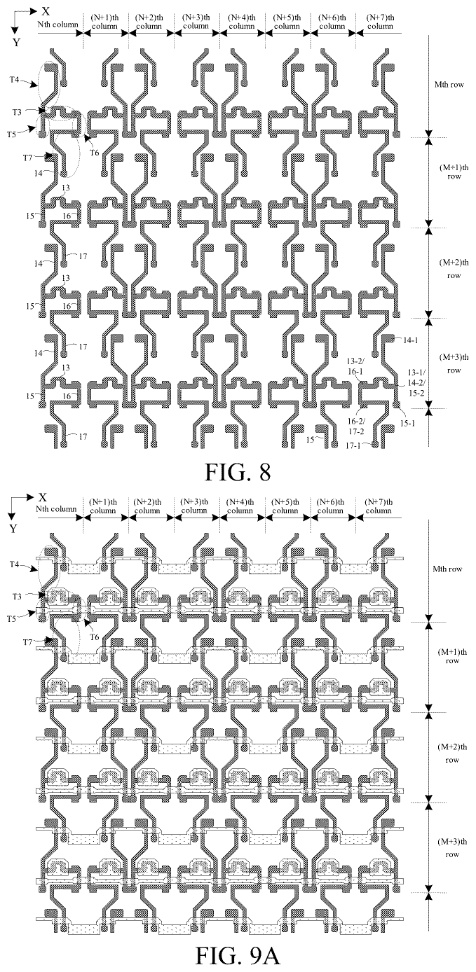

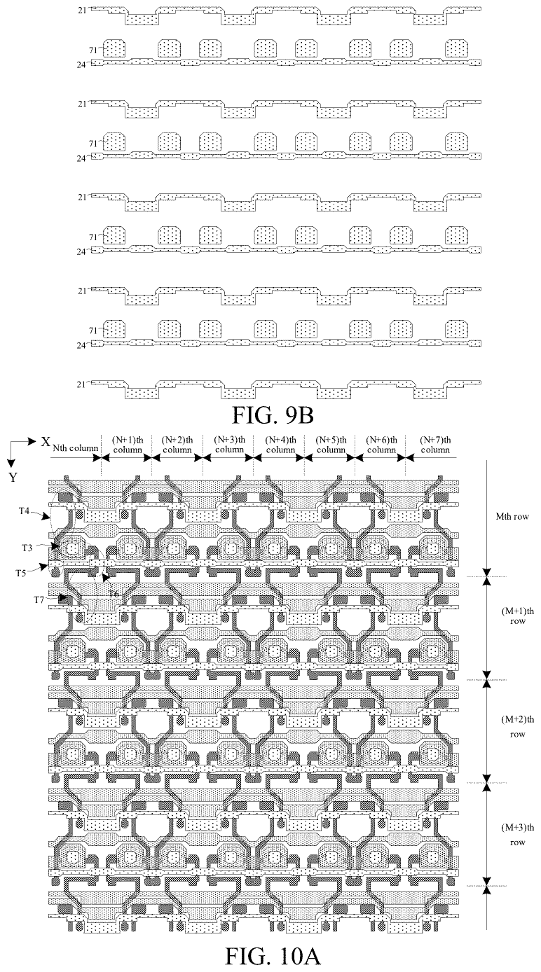

In an exemplary implementation mode, the first semiconductor layer may be made of poly Silicon (p-Si), i.e., the third transistor T3 to the seventh transistor T7 are LTPS transistors. In an exemplary implementation mode, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.
(2) A pattern of a first conductive layer is formed. In an exemplary implementation mode, forming the pattern of the first conductive layer may include: depositing sequentially a second insulation thin film and a first conductive thin film on the base substrate on which the aforementioned pattern is formed, and patterning the first conductive thin film through a patterning process to form a second insulation layer that covers the pattern of the first semiconductor layer and form the pattern of the first conductive layer disposed on the second insulation layer, as shown in FIG. 9A and FIG. 9B, and FIG. 9B is a schematic plan view of the first conductive layer in FIG. 9A. In an exemplary implementation mode, the first conductive layer may be referred to as a first gate metal (GATE1) layer.

In an exemplary implementation mode, a pattern of a first conductive layer of each circuit unit at least includes a first scan signal line 21, a light emitting signal line 24, and a first electrode plate 71 of a storage capacitor.

In an exemplary implementation mode, the first electrode plate 71 may be in a shape of a rectangle, and a chamfer may be provided at a corner of the rectangle. An orthographic projection of the first electrode plate 71 on the base substrate is at least partially overlapped with an orthographic projection of the third active layer of the third transistor T3 on the base substrate. In an exemplary implementation mode, the first electrode plate 71 may simultaneously serve as a lower electrode plate of the storage capacitor and a gate electrode of the third transistor T3.

In an exemplary implementation mode, the first scan signal line 21 may be in a shape of a straight line or a polyline in which a main body portion extends along the first direction X, the first scan signal line 21 may be located on a side of the first electrode plate 71 in an opposite direction of the second direction Y, a region where the first scan signal line 21 is overlapped with the fourth active layer may serve as a gate electrode of the fourth transistor T4, and a region where the first scan signal line 21 is overlapped with the seventh active layer may serve as a gate electrode of the seventh transistor T7.

In the present disclosure, “A extends along a B direction” refers to that A may include a main body portion and a secondary portion connected with the main body portion, wherein the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

In an exemplary implementation mode, since the seventh active layer 17 is provided across two adjacent circuit units, for a first scan signal line 21 of a present unit row, turn-on and turn-off of a fourth transistor T4 in a pixel drive circuit of the present unit row is controlled on one hand, and turn-on and turn-off of a seventh transistor T7 in a pixel drive circuit of a previous unit row is controlled on the other hand. For example, a first scan signal line 21 of the (M+1)th unit row may control a fourth transistor T4 in a pixel drive circuit of the (M+1)th unit row and a seventh transistor T7 in a pixel drive circuit of the Mth unit row. For another example, a first scan signal line 21 of the (M+2)th unit row may control a fourth transistor T4 in a pixel drive circuit of the (M+2)th unit row and a seventh transistor T7 in a pixel drive circuit of the (M+1)th unit row. For another example, a first scan signal line 21 of the (M+3)th unit row may control a fourth transistor T4 in a pixel drive circuit of the (M+3)th unit row and a seventh transistor T7 in a pixel drive circuit of the (M+2)th unit row.

In an exemplary implementation mode, the light emitting signal line 24 may be in a shape of a straight line or a polyline in which a main body portion extends along the first direction X, the light emitting signal line 24 may be located a side of the first electrode plate 71 in the second direction, a region where the light emitting signal line 24 is overlapped with the fifth active layer may serve as a gate electrode of the fifth transistor T5, and a region where the light emitting signal line 24 is overlapped with the sixth active layer may serve as a gate electrode of the sixth transistor T6.

In an exemplary implementation mode, the first scan signal line 21 and the light emitting signal line 24 may be polylines with unequal widths, and the widths are dimensions in the second direction Y, so that not only a layout of a pixel structure may be facilitated, but also a parasitic capacitance between signal lines may be reduced, which is not limited here in the present disclosure.

In an exemplary implementation mode, the light emitting signal line 24 may include a region overlapping with the first semiconductor layer and a region not overlapping with the first semiconductor layer, and a width of a signal line in the region overlapping with the first semiconductor layer may be greater than a width of a signal line in the region not overlapping with the first semiconductor layer.

In an exemplary implementation mode, first conductive layers of adjacent unit columns may be mirror symmetric with respect to a column dividing line. For example, a first conductive layer in the Nth unit column and a first conductive layer in the (N+1)th unit column may be mirror symmetric with respect to a column dividing line. For another example, the first conductive layer in the (N+1)th unit column and a first conductive layer in the (N+2)th unit column may be mirror symmetric with respect to a column dividing line. For another example, the first conductive layer in the (N+2)th unit column and a first conductive layer in the (N+3)th unit column may be mirror symmetric with respect to a column dividing line.

In an exemplary implementation mode, shapes of first conductive layers in a plurality of unit rows may be substantially the same.

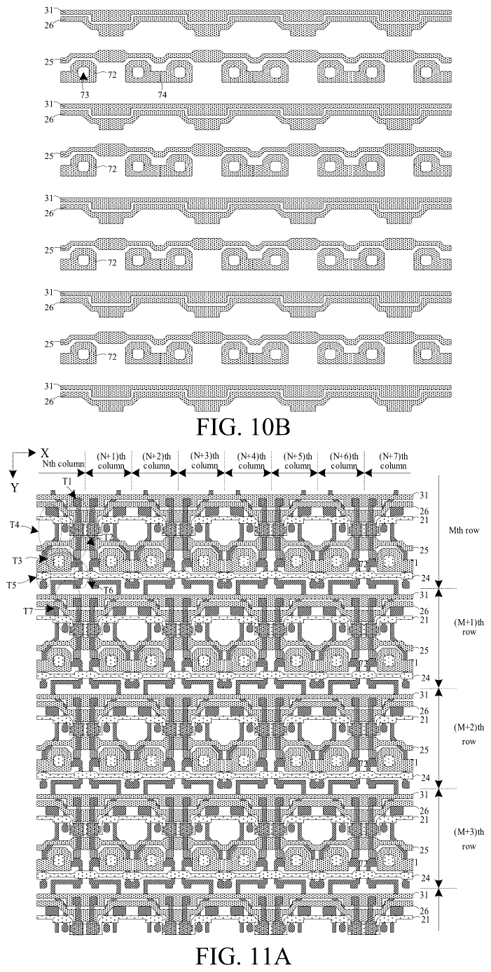

In an exemplary implementation mode, after the pattern of the first conductive layer is formed, a conductive treatment may be performed on the first semiconductor layer by using the first conductive layer as a shield. The first semiconductor layer, in a region which is shielded by the first conductive layer, forms channel regions of the third transistor T3 to the seventh transistor T7, and the semiconductor layer, in a region which is not shielded by the first conductive layer, is made to be conductive, that is, first regions and second regions of the third transistor T3 to the seventh transistor T7 are all made to be conductive.
(3) A pattern of a second conductive layer is formed. In an exemplary implementation mode, forming a pattern of a second conductive layer may include: depositing sequentially a third insulation thin film and a second conductive thin film on the base substrate on which the aforementioned patterns are formed, and the second conductive thin film is patterned through a patterning process to form a third insulation layer that covers the first conductive layer and the pattern of the second conductive layer provided on the third insulation layer, as shown in FIG. 10A and FIG. 10B. FIG. 10B is a schematic plan view of the second conductive layer in FIG. 10A. In an exemplary implementation mode, the second conductive layer may be referred to as a second gate metal (GATE2) layer.

In an exemplary implementation mode, the pattern of the second conductive layer of each circuit unit at least includes a first shielding line 25, a second shielding line 26, a first initial signal line 31, and a second electrode plate 72 of the storage capacitor.

In an exemplary implementation mode, a profile of the second electrode plate 72 may be in a shape of a rectangle, a chamfer may be provided at a corner of the rectangle, an orthographic projection of the second electrode plate 72 on the base substrate is at least overlapped with an orthographic projection of the first electrode plate 71 on the base substrate, the second electrode plate 72 may serve as an upper electrode plate of the storage capacitor, and the first electrode plate 71 and the second electrode plate 72 constitute the storage capacitor of the pixel drive circuit.

In an exemplary implementation mode, the second electrode plate 72 is provided with an opening 73. The opening 73 may have a rectangular shape and may be located in a middle region of the second electrode plate 72, so that the second electrode plate 72 is formed in an annular structure. The opening 73 exposes the third insulation layer covering the first electrode plate 71, and an orthographic projection of the first electrode plate 71 on the base substrate contains an orthographic projection of the opening 73 on the base substrate. In an exemplary implementation mode, the opening 73 is configured to accommodate a ninth via formed subsequently, and the ninth via is located within the opening 73 and exposes the first electrode plate 71, so that a first connection electrode formed subsequently is connected with the first electrode plate 71.

In an exemplary implementation mode, in a unit row, second electrode plates 72 in some two adjacent circuit units may be connected with each other through a plate electrode connection strip 74, so that the second electrode plates 72 in the two adjacent circuit units are of an interconnected integral structure. For example, a second electrode plate 72 of the (N+1)th unit column and a second electrode plate 72 of the (N+2)th unit column may be of an interconnected integral structure. For another example, a second electrode plate 72 of the (N+3)th unit column and a second electrode plate 72 of the (N+4)th unit column may be of an interconnected integral structure. For another example, a second electrode plate 72 of the (N+5)th unit column and a second electrode plate 72 of the (N+6)th unit column may be of an interconnected integral structure. Since a second electrode plate 72 in each circuit unit is configured to be connected with a first power supply line formed subsequently, by forming second electrode plates 72 of some adjacent circuit units into an interconnected integral structure, it is not only possible to reduce an occupied area of the pixel drive circuit, which is conducive to improving a resolution, but also to ensure that second electrode plates 72 of the adjacent circuit units have a same potential, which is conducive to improving uniformity of a panel, avoiding poor display of the display substrate, and ensuring a display effect of the display substrate.

In an exemplary implementation mode, the first shielding line 25 may be in a shape of a straight line or a polyline in which a main body portion extends along the first direction X, the first shielding line 25 may be located between the first scan signal line 21 and the second electrode plate 72, and the first shielding line 25 is configured as a shielding layer of the second transistor T2, shielding a channel region of the second transistor T2 and ensuring electrical performance of the oxide second transistor T2, and is simultaneously configured to serve as a bottom gate electrode of the second transistor T2.

In an exemplary implementation mode, the second shielding line 26 may be in a shape of a straight line or a polyline in which a main body portion extends along the first direction X, the second shielding line 26 may be located on a side of the first scan signal line 21 away from the second electrode plate 72, and the second shielding line 26 is configured as a shielding layer of the first transistor T1, shielding a channel region of the first transistor T1 and ensuring electrical performance of the oxide first transistor T1, and is simultaneously configured to serve as a bottom gate electrode of the first transistor T1.

In an exemplary implementation mode, the first initial signal line 31 may be in a shape of a straight line or a polyline in which a main body portion extends along the first direction X, the first initial signal line 31 may be located on a side of the second shielding line 26 away from the second electrode plate 72, and the first initial signal line 31 is configured to write a first initial signal to the first electrode of the first transistor T1 through a connection between a sixth connection electrode formed subsequently and the first region of the first active layer.

In an exemplary implementation mode, second conductive layers of adjacent unit columns may be mirror symmetric with respect to a column dividing line. For example, a second conductive layer in the Nth unit column and a second conductive layer in the (N+1)th unit column may be mirror symmetric with respect to a column dividing line. For another example, the second conductive layer in the (N+1)th unit column and a second conductive layer in the (N+2)th unit column may be mirror symmetric with respect to a column dividing line. For another example, the second conductive layer in the (N+2)th unit column and a second conductive layer in the (N+3)th unit column may be mirror symmetric with respect to a column dividing line.

In an exemplary implementation mode, shapes of second conductive layers in a plurality of unit rows may be substantially the same.
(4) A pattern of a second semiconductor layer is formed. In an exemplary implementation mode, forming the pattern of the second semiconductor layer may include: depositing a fourth insulation thin film and a second semiconductor thin film sequentially on the base substrate on which the above-mentioned patterns are formed, patterning the second semiconductor thin film through a patterning process to form a fourth insulation layer that covers the base substrate and the pattern of the second semiconductor layer disposed on the fourth insulation layer, as shown in FIG. 11A and FIG. 11B, and FIG. 11B is a schematic plan view of the second conductive layer in FIG. 11A.

In an exemplary implementation mode, a pattern of a second semiconductor layer of each circuit unit at least includes a first active layer 11 of the first transistor T1 and a second active layer 12 of the second transistor T2.

In an exemplary implementation mode, the first active layer 11 and the second active layer 12 may be in a shape of a strip shape extending in the second direction Y, an orthographic projection of the first active layer 11 on the base substrate is at least partially overlapped with an orthographic projection of the second shielding line 26 on the base substrate, and an orthographic projection of the second active layer 12 on the base substrate is at least partially overlapped with an orthographic projection of the first shielding line 25 on the base substrate.

In an exemplary implementation mode, both the first active layer 11 and the second active layer 12 may include a first region, a second region, and a channel region located between the first region and the second region. A first region 11-1 of the first active layer may be located on a side of the second shielding line 26 away from the second electrode plate 72, and a second region 11-2 of the first active layer may be located on a side of the second shielding line 26 close to the second electrode plate 72. A first region 12-1 of the second active layer may be located on a side of the first shielding line 25 away from the second electrode plate 72, and a second region 12-2 of the second active layer may be located on a side of the first shielding line 25 close to the second electrode plate 72.

In an exemplary implementation mode, the first region 11-1 of the first active layer and the second region 12-2 of the second active layer may be separately provided, the second region 11-2 of the first active layer and the first region 12-1 of the second active layer may be connected with each other, that is, the second region 11-2 of the first active layer may serve as the first region 12-1 of the second active layer.

In an exemplary implementation mode, second semiconductor layers of adjacent unit columns may be mirror symmetric with respect to a column dividing line. For example, a second semiconductor layer in the Nth unit column and a second semiconductor layer in the (N+1)th unit column may be mirror symmetric with respect to a column dividing line. For another example, the second semiconductor layer in the (N+1)th unit column and a second semiconductor layer in the (N+2)th unit column may be mirror symmetric with respect to a column dividing line. For yet another example, the second semiconductor layer in the (N+2)th unit column and a second semiconductor layer in the (N+3)th unit column may be mirror symmetric with respect to a column dividing line.

In an exemplary implementation mode, shapes of second semiconductor layers in a plurality of unit rows may be substantially the same.

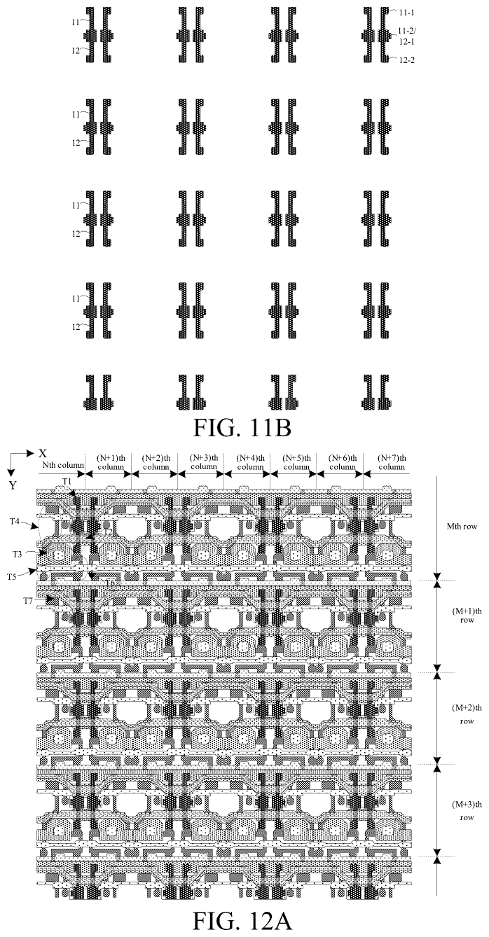

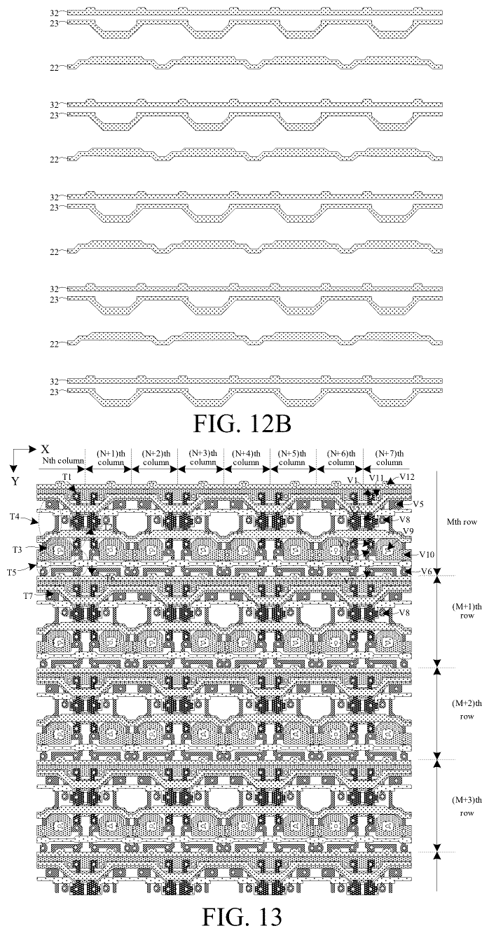

In an exemplary implementation mode, the second semiconductor layer may be made of an oxide, i.e., an eighth transistor T8 is an oxide transistor. In an exemplary implementation mode, the second semiconductor thin film may be made of Indium Gallium Zinc Oxide (IGZO), wherein an electron mobility of the Indium Gallium Zinc Oxide (IGZO) is higher than that of amorphous silicon.
(5) A pattern of a third conductive layer is formed. In an exemplary implementation mode, forming the pattern of the third conductive layer may include: depositing a fifth insulation thin film and a third conductive thin film sequentially on the base substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIG. 12A and FIG. 12B, FIG. 12B is a schematic plan view of the third conductive layer in FIG. 12A. In an exemplary implementation mode, the second conductive layer may be referred to as a third gate metal (GATE3) layer.

In an exemplary implementation mode, a pattern of a third conductive layer of each circuit unit at least includes a second scan signal line 22 and a third scan signal line 23, and a second initial signal line 32.

In an exemplary implementation mode, the second scan signal line 22 may be in a shape of a straight line or a polyline in which a main body portion extends along the first direction X, the second scan signal line 22 may be located between the first scan signal line 21 and the second electrode plate 72, and a region where the second scan signal line 22 is overlapped with the second active layer may serve as a gate electrode of the second transistor T2.

In an exemplary implementation mode, an orthographic projection of the second scan signal line 22 on the base substrate is at least partially overlapped with an orthographic projection of the first shielding line 25 on the base substrate, and the second scan signal line 22 and the first shielding line 25 may be connected with a same signal source, so that the first shielding line 25 may serve as a bottom gate electrode of the second transistor T2, and the second scan signal line 22 may serve as a top gate electrode of the second transistor T2, to form the second transistor T2 with a top gate and bottom gate structure.

In an exemplary implementation mode, the third scan signal line 23 may be in a shape of a straight line or a polyline in which a main body portion extends along the first direction X, the third scan signal line 23 may be located at a side of the second scan signal line 22 away from the second electrode plate 72, and a region where the third scan signal line 23 is overlapped with the first active layer may serve as the gate electrode of the first transistor T1.

In an exemplary implementation mode, an orthographic projection of the third scan signal line 23 on the base substrate is at least partially overlapped with an orthographic projection of the second shielding line 26 on the base substrate, and the third scan signal line 23 and the second shielding line 26 may be connected with a same signal source, so that the second shielding line 26 may serve as a bottom gate electrode of the first transistor T1, and the third scan signal line 23 may serve as a top gate electrode of the first transistor T1, to form the first transistor T1 with a top gate and bottom gate structure.

In an exemplary implementation mode, the second initial signal line 32 may be in a shape of a straight line or a polyline in which a main body portion extends along the first direction X, the second initial signal line 32 may be located on a side of the first initial signal line 31 away from the second electrode plate 72, and the second initial signal line 32 is configured to write a second initial signal to the first electrode of the seventh transistor T7 through a connection between a seventh connection electrode formed subsequently and the first region of the seventh active layer.

In an exemplary implementation mode, third conductive layers of adjacent unit columns may be mirror symmetric with respect to a column dividing line. For example, a third conductive layer in the Nth unit column and a third conductive layer in the (N+1)th unit column may be mirror symmetric with respect to a column dividing line. For another example, the third conductive layer in the (N+1)th unit column and a third conductive layer in the (N+2)th unit column may be mirror symmetric with respect to a column dividing line. For another example, the third conductive layer in the (N+2)th unit column and a third conductive layer in the (N+3)th unit column may be mirror symmetric with respect to a column dividing line.

In an exemplary implementation mode, shapes of third conductive layers in a plurality of unit rows may be substantially the same.
(6) A pattern of a sixth insulation layer is formed. In an exemplary implementation mode, forming the pattern of the sixth insulation layer may include: depositing a sixth insulation thin film on the base substrate on which the aforementioned patterns are formed, patterning the fifth insulation thin film using a patterning process to form a sixth insulation layer covering the third conductive layer, wherein a plurality of vias are provided on the sixth insulation layer, as shown in FIG. 13.

In an exemplary implementation mode, a plurality of vias of each circuit unit at least include: a first via V1, a second via V2, a third via V3, a fourth via V4, a fifth via V5, a sixth via V6, a seventh via V7, an eighth via V8, a ninth via V9, a tenth via V10, an eleventh via V11, and a twelfth via V12.

In an exemplary implementation mode, an orthographic projection of the first via V1 on the base substrate is within a range of an orthographic projection of the first region of the first active layer on the base substrate, the sixth insulation layer and the fifth insulation layer within the first via V1 are etched away to expose a surface of the first region of the first active layer, and the first via V1 is configured such that a sixth connection electrode formed subsequently is connected with the first region of the first active layer through the via.

In an exemplary implementation mode, an orthographic projection of the second via V2 on the base substrate is within a range of an orthographic projection of the second region of the first active layer (also the first region of the second active layer) on the base substrate. The sixth insulation layer and the fifth insulation layer within the second via V2 are etched away to expose a surface of the second region of the first active layer (also the first region of the second active layer), and the second via V2 is configured such that a first connection electrode formed subsequently is connected with the second region of the first active layer (also the first region of the second active layer) through the via.

In an exemplary implementation mode, an orthographic projection of the third via V3 on the base substrate is within a range of an orthographic projection of the second region of the second active layer on the base substrate, the sixth insulation layer and the fifth insulation layer within the third via V3 are etched away to expose a surface of the second region of the second active layer, and the third via V3 is configured such that a second connection electrode formed subsequently is connected with the second region of the second active layer through the via.

In an exemplary implementation mode, an orthographic projection of the fourth via V4 on the base substrate is within an orthographic projection of the second region of the third active layer (also the first region of the sixth active layer) on the base substrate, the sixth insulation layer, the fifth insulation layer, the fourth insulation layer, the third insulation layer, and the second insulation layer within the fourth via V4 are etched away to expose a surface of the second region of the third active layer (also the first region of the sixth active layer), and the fourth via V4 is configured such that a second connection electrode formed subsequently is connected with the second region of the third active layer (also the first region of the sixth active layer) through the via.

In an exemplary implementation mode, an orthographic projection of the fifth via V5 on the base substrate is within a range of an orthographic projection of the first region of the fourth active layer on the base substrate, the sixth insulation layer, the fifth insulation layer, the fourth insulation layer, the third insulation layer, and the second insulation layer within the fifth via V5 are etched away to expose a surface of the first region of the fourth active layer, and the fifth via V5 is configured such that a third connection electrode formed subsequently is connected with the first region of the fourth active layer through the via.

In an exemplary implementation mode, an orthographic projection of the sixth via V6 on the base substrate is within a range of an orthographic projection of the first region of the fifth active layer on the base substrate, the sixth insulation layer, the fifth insulation layer, the fourth insulation layer, the third insulation layer, and the second insulation layer within the sixth via V6 are etched away to expose a surface of the first region of the fifth active layer, and the sixth via V6 is configured such that a fourth connection electrode formed subsequently is connected with the first region of the fifth active layer through the via.

In an exemplary implementation mode, an orthographic projection of the seventh via V7 on the base substrate is within a range of an orthographic projection of the second region of the sixth active layer (also the second region of the seventh active layer) on the base substrate. The sixth insulation layer, the fifth insulation layer, the fourth insulation layer, the third insulation layer, and the second insulation layer within the seventh via V7 are etched away to expose a surface of the second region of the sixth active layer (also the second region of the seventh active layer), and the seventh via V7 is configured such that a fifth connection electrode formed subsequently is connected with the second region of the sixth active layer (also the second region of the seventh active layer) through the via.

In an exemplary implementation mode, an orthographic projection of the eighth via V8 on the base substrate is within a range of an orthographic projection of the first region of the seventh active layer on the base substrate. The sixth insulation layer, the fifth insulation layer, the fourth insulation layer, the third insulation layer, and the second insulation layer within the eighth via V8 are etched away to expose a surface of the first region of the seventh active layer, and the eighth via V8 is configured such that a seventh connection electrode formed subsequently is connected with the first region of the seventh active layer through the via.

In an exemplary implementation mode, an orthographic projection of the ninth via V9 on the base substrate is within a range of an orthographic projection of the opening 73 on the base substrate, the sixth insulation layer, the fifth insulation layer, the fourth insulation layer, and the third insulation layer within the ninth via V9 are etched away to expose a surface of the first electrode plate 71, and the ninth via V9 is configured such that a first connection electrode formed subsequently is connected with the first electrode plate 71 through the via.

In an exemplary implementation mode, an orthographic projection of the tenth via V10 on the base substrate is within a range of an orthographic projection of the plate electrode connection strip 74 of the second electrode plate 72 on the base substrate, the sixth insulation layer, the fifth insulation layer, and the fourth insulation layer within the tenth via V10 are etched away to expose a surface of the plate electrode connection strip 74, and the tenth via V10 is configured such that a fourth connection electrode formed subsequently is connected with the plate electrode connection strip 74 through the via.

In an exemplary implementation mode, an orthographic projection of the eleventh via V11 on the base substrate is within a range of an orthographic projection of the first initial signal line 31 on the base substrate, the sixth insulation layer, the fifth insulation layer, and the fourth insulation layer within the eleventh via V11 is etched away to expose a surface of the first initial signal line 31, and the eleventh via V11 is configured such that a sixth connection electrode formed subsequently is connected with the first initial signal line 31 through the via.

In an exemplary implementation mode, an orthographic projection of the twelfth via V12 on the base substrate is within a range of an orthographic projection of the second initial signal line 32 on the base substrate, the sixth insulation layer within the twelfth via V12 is etched away to expose a surface of the second initial signal line 32, and the twelfth via V12 is configured such that a seven connection electrode formed subsequently is connected with the second initial signal line 32 through the via.

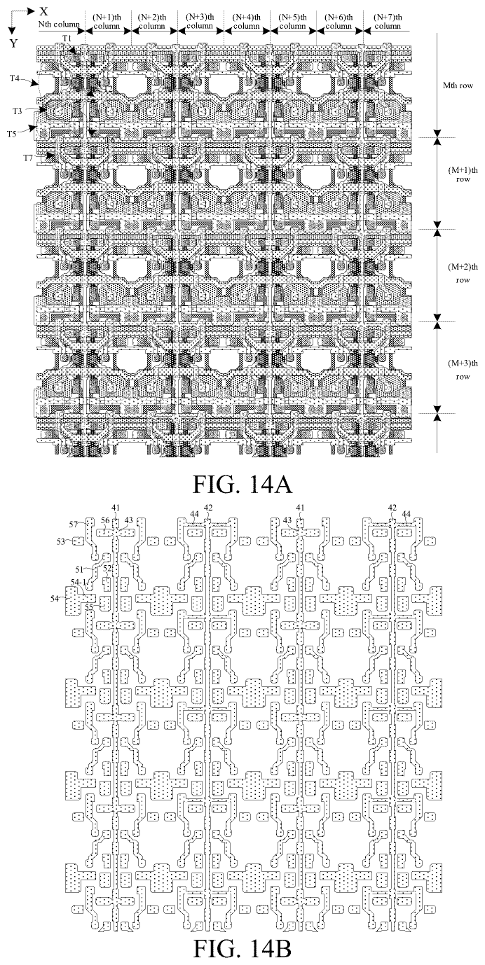

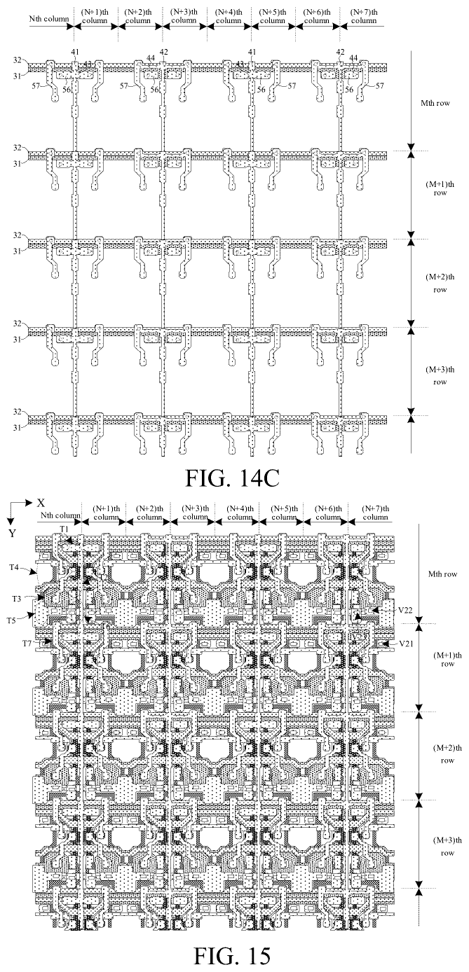

In an exemplary implementation mode, a plurality of vias of adjacent unit columns may be mirror symmetric with respect to a column dividing line, and shapes of a plurality of vias in a plurality of unit rows may be substantially the same.
(7) A pattern of a fourth conductive layer is formed. In an exemplary implementation mode, forming the pattern of the fourth conductive layer may include: depositing a fourth conductive thin film on the base substrate on which the aforementioned patterns are formed, and patterning the fourth conductive thin film using a patterning process to form the fourth conductive layer disposed on the sixth insulation layer, as shown in FIG. 14A and FIG. 14B, and FIG. 14B is a schematic plan view of the fourth conductive layer in FIG. 14A. In an exemplary implementation mode, the fourth conductive layer may be referred to as a first source drain metal (SD1) layer.

In an exemplary implementation mode, a fourth conductive layer of each circuit unit includes at least a first connection electrode 51, a second connection electrode 52, a third connection electrode 53, a fourth connection electrode 54, a fifth connection electrode 55, a sixth connection electrode 56, and a seventh connection electrode 57.

In an exemplary implementation mode, the first connection electrode 51 may be in a shape of a polyline in which a main body portion extends along the second direction Y, a first end of the first connection electrode 51 is connected with the second region of the first active layer (also the first region of the second active layer) through the second via V2, and after a second end of the first connection electrode 51 extends toward a direction of the first electrode plate 71, the second end of the first connection electrode 51 is connected with the first electrode plate 71 through the ninth via V9. In an exemplary implementation mode, since the first electrode plate 71 simultaneously serves as a gate electrode of the third transistor T3, the first connection electrode 51 enables the second electrode of the first transistor T1, the first electrode of the second transistor T2, the gate electrode of the third transistor T3, and the first electrode plate 71 to have a same potential and form a first node N1 of the pixel drive circuit.

In an exemplary implementation mode, the second connection electrode 52 may be in a shape of a strip in which a main body portion extends along the second direction Y, a first end of the second connection electrode 52 is connected with the second region of the second active layer through the third via V3, and a second end of the second connection electrode 52 is connected with the second region of the third active layer (also the first region of the sixth active layer) through the fourth via V4. In an exemplary implementation mode, the second connection electrode 52 enables the second electrode of the second transistor T2, the second electrode of the third transistor T3, and the first electrode of the sixth transistor T6 to have a same potential and form a third node N3 of the pixel drive circuit.

In an exemplary implementation mode, the third connection electrode 53 may have a block shape (e.g., a rectangular shape), and the third connection electrode 53 is connected with the first region of the fourth active layer through the fifth via V5. In an exemplary implementation mode, the third connection electrode 53 may serve as the first electrode of the fourth transistor T4, and the third connection electrode 53 is configured to be connected with a data signal line formed subsequently.

In an exemplary implementation mode, the fourth connection electrode 54 may have a block shape (e.g., a rectangular shape), a first end of the fourth connection electrode 54 is connected with the first region of the fifth active layer through the sixth via V6, and a second end of the fourth connection electrode 54 is connected with the plate electrode connection strip 74 through the tenth via V10. Since the plate electrode connection strip 74 is connected with the second electrode plate 72, the fourth connection electrode 54 enables the first electrode of the fifth transistor T5 and the second electrode plate 72 of the storage capacitor in each circuit unit to have a same potential.

In an exemplary implementation mode, a power supply connection block 54-1 is provided on the fourth connection electrode 54 in each circuit unit. A shape of the power supply connection block 54-1 may be a strip shape extending along the first direction X, a first end of the power supply connection block 54-1 is connected with the fourth connection electrode 54, a second end of the power supply connection block 54-1 extends toward a direction away from the fourth connection electrode 54, and the power supply connection block 54-1 is configured to be connected with a first power supply line formed subsequently.

In an exemplary implementation mode, in one unit row, fourth connection electrodes 54 in some two adjacent circuit units may be connected with each other, so that the fourth connection electrodes in the two adjacent circuit units are of an interconnected integral structure. For example, a fourth connection electrode 54 of the (N+1)th unit column and a fourth connection electrode 54 of the (N+2)th unit column may be of an interconnected integral structure. For another example, a fourth connection electrode 54 of the (N+3)th unit column and a fourth connection electrode 54 of the (N+4)th unit column may be of an interconnected integral structure. For another example, a fourth connection electrode 54 of the (N+5)th unit column and a fourth connection electrode 54 of the (N+6)th unit column may be of an interconnected integral structure. Since a fourth connection electrode 54 in each circuit unit is configured to be connected with a first power supply line formed subsequently, by forming fourth connection electrodes 54 of some adjacent circuit units into an interconnected integral structure, it is not only possible to reduce an occupied area of the pixel drive circuit, which is conducive to improving a resolution, but also to ensure that fourth connection electrodes 54 of adjacent circuit units have a same potential, which is conducive to improving uniformity of a panel, avoiding poor display of the display substrate, and ensuring a display effect of the display substrate.

In an exemplary implementation mode, a shape of the fifth connection electrode 55 may be a block shape (e.g., a rectangular shape), and the fifth connection electrode 55 is connected with the second region of the sixth active layer (also the second region of the seventh active layer) through the seventh via V7. In an exemplary implementation mode, the fifth connection electrode 55 forms a fourth node N4 of the pixel drive circuit, and is configured to be connected with an anode connection electrode formed subsequently.

In an exemplary implementation mode, the sixth connection electrode 56 may be in a shape of a strip in which a main body portion extends along the first direction X, a first end of the six connection electrode 56 is connected with the first region of the first active layer through the first via V1, and a second end of the sixth connection electrode 46 is connected with the first initial signal line 31 through the eleventh via V11. In an exemplary implementation mode, the sixth connection electrode 56 achieves a connection between the first initial signal line 31 and the first electrode of the first transistor T1, and a first initial signal transmitted by the first initial signal line 31 may be written to the first electrode of the first transistor T1.

In an exemplary implementation mode, the seventh connection electrode 57 may be in a shape of a strip in which a main body portion extends along the second direction Y, a first end of the seventh connection electrode 57 is connected with the first region of the seventh active layer through the eighth via V8, and a second end of the seventh connection electrode 47 is connected with the second initial signal line 32 through the twelfth via V12. In an exemplary implementation mode, the seventh connection electrode 57 achieves a connection between the second initial signal line 32 and the first electrode of the seventh transistor T7, and a second initial signal transmitted by the second initial signal line 32 may be written to the first electrode of the seventh transistor T7.

In an exemplary implementation mode, the fourth conductive layer may also include a first initial connection line 41, a second initial connection line 42, a first initial connection strip 43, and a second initial connection strip 44.

In an exemplary implementation mode, the first initial connection line 41 may be in a shape of a straight line or a polyline in which a main body portion extends in the second direction Y, and in at least one circuit unit, the first initial connection line 41 may be disposed on a side of the sixth connection electrode 56 away from the seventh connection electrode 57. The first initial connection strip 43 may be in a strip shape extending in the first direction X, and may be disposed between the first initial connection line 41 and the sixth connection electrode 56, a first end of the first initial connection strip 43 is connected with the first initial connection line 41, and a second end of the first initial connection strip 43 is connected with the sixth connection electrode 56.

In an exemplary implementation mode, since the sixth connection electrode 56 in each circuit unit is connected with the first initial signal line 31, an interconnection between the first initial signal line 31 whose main body portion extends along the first direction X and the first initial connection line 41 whose main body portion extends along the second direction Y is achieved, so that the first initial signal line 31 and the first initial connection line 41 form a mesh communication structure transmitting the first initial signal on the display substrate, not only a resistance of the first initial signal line is effectively reduced, a voltage drop of the first initial signal may be reduced, but also uniformity of the first initial signal in the display substrate may be effectively improved, display uniformity may be effectively improved, and display character and display quality may be improved.

In an exemplary implementation mode, the first initial connection line 41 and the first initial connection strip 43 may be provided in circuit units of some unit columns. For example, circuit units of the Nth unit column and the (N+1)th unit column are provided with the first initial connection line 41 and the first initial connection strip 43. For another example, circuit units of the (N+4)th unit column and the (N+5)th unit column are provided with the first initial connection line 41 and the first initial connection strip 43.

In an exemplary implementation mode, adjacent unit columns may share a same first initial connection line 41. For example, the Nth unit column and the N+1 unit column may share a same first initial connection line 41, and one first initial connection line 41, a plurality of first initial connection strips 43, and a plurality of sixth connection electrodes 56 in e two unit columns may be of an interconnected integral structure. For another example, the (N+4)th unit column and the (N+5)th unit column may share a same first initial connection line 41, and one first initial connection line 41, a plurality of first initial connection strips 43, and a plurality of sixth connection electrodes 56 in two unit columns may be of an interconnected integral structure.

In an exemplary implementation mode, the second initial connection line 42 may be in a shape of a straight line or a polyline in which a main body portion extends along the second direction Y, and in at least one circuit unit, the second initial connection line 42 may be provided on a side of the sixth connection electrode 56 away from the seventh connection electrode 57. The second initial connection strip 44 may be in a shape of a strip extending along the first direction X, and may be provided between the second initial connection line 42 and the seventh connection electrode 57, a first end of the second initial connection strip 44 is connected with the second initial connection line 42, and a second end of the second initial connection strip 44 is connected with the seventh connection electrode 57.

In an exemplary implementation mode, since the seventh connection electrode 57 in each circuit unit is connected with the second initial signal line 32. A connection between the second initial signal line 32 whose main body portion extends along the first direction X and the second initial connection line 42 whose main body portions extends along the second direction Y is achieved, so that the second initial signal line 32 and the second initial connection line 42 form a mesh communication structure transmitting the second initial signal on the display substrate, not only a resistance of the second initial signal line may be effectively reduced, a voltage drop of the second initial signal may be reduced, but also uniformity of the second initial signal in the display substrate may be effectively improved, display uniformity may be effectively improved, and display character and display quality may be improved.

In an exemplary implementation mode, the second initial connection line 42 and the second initial connection strip 44 may be provided in circuit units of some unit columns. For example, circuit units of the (N+2)th unit column and the (N+3)th unit column are provide with the second initial connection line 42 and the second initial connection strip 44. For another example, circuit units of the (N+6)th unit column and the (N+7)th unit column are provide with the second initial connection line 42 and the second initial connection strip 44.

In an exemplary implementation mode, adjacent unit columns may share a same second initial connection line 42. For example, the (N+2)th unit column and the (N+3)th unit column may share a same second initial connection line 42, and one second initial connection line 42, a plurality of second initial connection strips 44, and a plurality of seventh connection electrodes 57 in two unit columns may be of an interconnected integral structure. For another example, the (N+4)th unit column and the (N+5)th unit column may share a same second initial connection line 42, and one second initial connection line 42, a plurality of second initial connection strips 44, and a plurality of seventh connection electrodes 57 in two unit columns may be of an interconnected integral structure.

FIG. 14C is a schematic diagram of a mesh communication structure of initial signals according to an exemplary embodiment of the present disclosure. As shown in FIG. 14C, in the first direction X, the first initial connection line 41 and the second initial connection line 42 may be alternately disposed, that is, one second initial connection line 42 may be disposed between two adjacent first initial connection lines 41 in the first direction X, and one first initial connection line 41 may be disposed between two adjacent second initial connection lines 42 in the first direction X.

In an exemplary implementation mode, two unit columns may be arranged to form a unit column group, a unit column group provided with the first initial connection line 41 and a unit column group provided with the second initial connection line 42 are alternately arranged. Or, four unit columns may be arranged to form a unit column group, and a unit column group provided with the first initial connection line 41 and a unit column group provided with the second initial connection line 42 may be alternately arranged.

In an exemplary implementation mode, first connection electrodes 51 to seventh connection electrodes 57 of adjacent unit columns may be mirror symmetric with respect to a column dividing line, and shapes of first connection electrodes 51 to seventh connection electrodes 57 in a plurality of unit rows may be substantially the same.
(8) A pattern of a first planarization layer is formed. In an exemplary implementation mode, forming the pattern of the first planarization layer may include: coating a first planarization thin film on the base substrate on which the aforementioned patterns are formed, patterning the first planarization thin film using a patterning process to form a first planarization layer covering the pattern of the fourth conductive layer, wherein the first planarization layer is provided with a plurality of vias, as shown in FIG. 15.

In an exemplary implementation mode, the plurality of vias in each circuit unit at least includes a twenty-first via V21, a twenty-second via V22, and a twenty-third via V23.

In an exemplary implementation modes, an orthographic projection of the twenty-first via V21 on the base substrate is located within a range of an orthographic projection of the third connection electrode 53 on the base substrate, the first planarization layer within the twenty-first via V21 is removed to expose a surface of the third connection electrode 53, and the twenty-first via V21 is configured such that a data signal line formed subsequently is connected with the third connection electrode 53 through the via.

In an exemplary implementation mode, an orthographic projection of the twenty-second via V22 on the base substrate is within a range of an orthographic projection of the power supply connection block 54-1 of the fourth connection electrode 54 on the base substrate, the first planarization layer within the twenty-second via V22 is etched away to expose a surface of the power supply connection block 54-1, and the twenty-second via V22 is configured such that a first power supply line formed subsequently is connected with the power supply connection block 54-1 through the via.

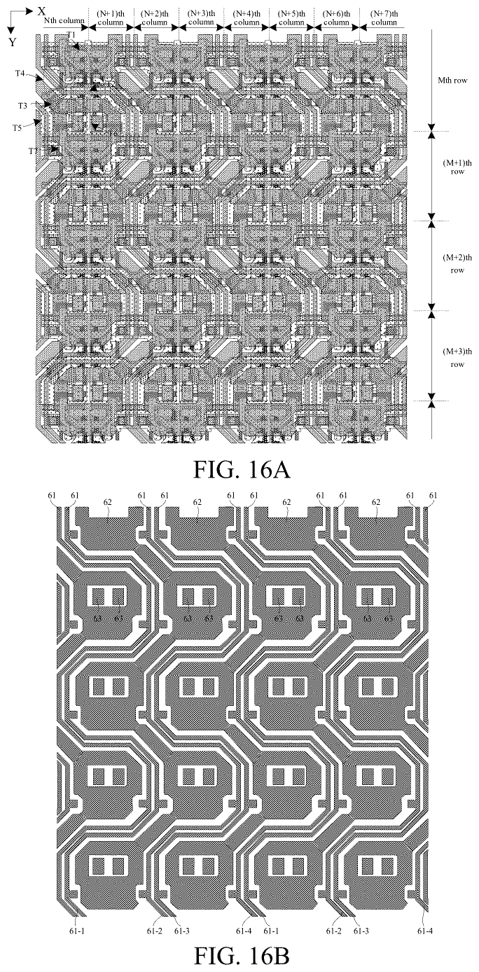

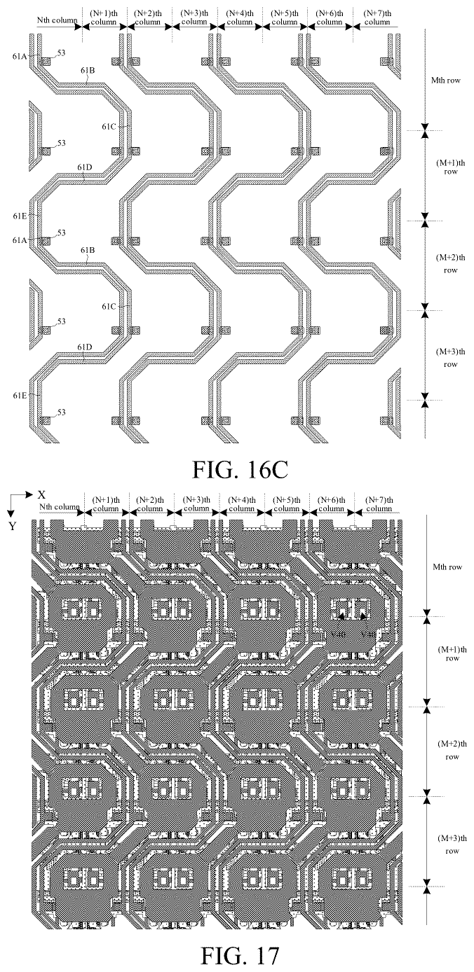

In an exemplary implementation mode, an orthographic projection of the twenty-third via V23 on the base substrate is within a range of an orthographic projection of the fifth connection electrode 55 on the base substrate, the first planarization layer within the twenty-third via V23 is removed to expose a surface of the fifth connection electrode 55, and the twenty-third via V23 is configured such that an anode connection electrode formed subsequently is connected with the fifth connection electrode 55 through the via.
(9) A pattern of a fifth conductive layer is formed. In an exemplary implementation mode, forming the fifth conductive layer may include: depositing a fifth conductive thin film on the base substrate on which the above-mentioned patterns are formed, and patterning the fifth conductive thin film using a patterning process to form the fifth conductive layer disposed on the first planarization layer, as shown in FIG. 16A and FIG. 16B, and FIG. 16B is a schematic plan view of the fifth conductive layer in FIG. 16A. In an exemplary implementation mode, the fifth conductive layer may be referred to as a second source-drain metal (SD2) layer.

In an exemplary implementation mode, a fifth conductive layer of each circuit unit at least includes a data signal line 61, a first power supply line 62, and an anode connection electrode 63.

In an exemplary implementation mode, the data signal line 61 may be in a shape of a character “S” in which a main body portion extends along the second direction Y, and the data signal line 61 may be connected with the third connection electrode 53 through the twenty-first via V21. Since the third connection electrode 53 is connected with the first region of the fourth active layer through a via, a connection between the data signal line 61 and the first electrode of the fourth transistor T4 is achieved, and the data signal line 61 may write a data signal to the first electrode of the fourth transistor T4.

In an exemplary implementation mode, the data signal line 61 may include a first data signal line 61-1, a second data signal line 61-2, a third data signal line 61-3, and a fourth data signal line 61-4, and the first data signal line 61-1, the second data signal line 61-2, the third data signal line 61-3, and the fourth data signal line 61-4 may be periodically arranged in the first direction X.

FIG. 16C is a schematic diagram showing a connection between a data signal line and a third connection electrode in FIG. 16A. As shown in FIG. 16C, at least one data signal line 61 may be provided across a plurality of unit columns and be connected with third connection electrodes 53 (first electrodes of fourth transistors T4) in different unit columns, respectively, and at least one data signal line 61 is connected with fourth transistors T4 in circuit units corresponding to light emitting units of a same color.

In an exemplary implementation mode, a connection mode of a data signal line and a pixel drive circuit may be as follows. For a first data signal line 61-1 transmitting a data signal of a red image, the first data signal line 61-1 extends first to a first circuit unit (corresponding to a red light emitting unit formed subsequently) of the Mth unit row and the Nth unit column, and is connected with a pixel drive circuit in the first circuit unit. Then the first data signal line 61-1 extends to a first circuit unit of the (M+1)th unit row and the (N+2)th unit column, and is connected with a pixel drive circuit in the first circuit unit. Then the first data signal line 61-1 extends to a first circuit unit of the (M+2)th unit row and the Nth unit column, and is connected with a pixel drive circuit in the first circuit unit. Then the first data signal line 61-1 extends to a first circuit unit of the (M+3)th unit row and the (N+2)th unit column, and is connected with a pixel drive circuit in the first circuit unit. Since the pixel drive circuit in the first circuit unit is connected with a first anode in a red light emitting unit formed subsequently, the first data signal line 61-1 is connected, thereby a connection between the first data signal line 61-1 and a pixel drive circuit driving the red light emitting unit is achieved.

In an exemplary implementation mode, the connection mode between the data signal line and the pixel drive circuit may be as follows. For a second data signal line 61-2 transmitting a data signal of a green image, the second data signal line 61-2 extends first to a second circuit unit (corresponding to a green light emitting unit formed subsequently) of the Mth unit row and the (N+1)th unit column, and is connected with a pixel drive circuit in the second circuit unit. Then the second data signal line 61-2 extends to a second circuit unit of the (M+1)th unit row and the (N+3)th unit column, and is connected with a pixel drive circuit in the second circuit unit. Then the second data signal line 61-2 extends to a second circuit unit of the (M+2)th unit row and the (N+1)th unit column, and is connected with a pixel drive circuit in the second circuit unit. Then the second data signal line 61-2 extends to a second circuit unit of the (M+3)th unit row and the (N+3)th unit column, and is connected with a pixel drive circuit in the second circuit unit. Since the pixel drive circuit in the second circuit unit is connected with a second anode in a green light emitting unit formed subsequently, thereby a connection between the second data signal line 61-2 and a pixel drive circuit driving the green light emitting unit is achieved.

In an exemplary implementation mode, the connection mode between the data signal line and the pixel drive circuit may be as follows. For a third data signal line 61-3 transmitting a data signal of a blue image, the third data signal line 61-3 extends first to a third circuit unit (corresponding to a blue light emitting unit formed subsequently) of the Mth unit row and the (N+2)th unit column, and is connected with a pixel drive circuit in the third circuit unit. Then the third data signal line 61-3 extends to a third circuit unit of the (M+1)th unit row and the (N+4)th unit column, and is connected with a pixel drive circuit in the third circuit unit. Then the third data signal line 61-3 extends to a third circuit unit of the (M+2)th unit row and the (N+2)th unit column, and is connected with a pixel drive circuit in the third circuit unit. Then the third data signal line 61-3 extends to a third circuit unit of the (M+3)th unit row and the (N+4)th unit column, and is connected with a pixel drive circuit in the third circuit unit. Since the pixel drive circuit in the third circuit unit is connected with a third anode in a blue light emitting unit formed subsequently, thereby a connection between the third data signal line 61-3 and a pixel drive circuit driving the blue light emitting unit is achieved.

In an exemplary implementation mode, the connection mode between the data signal line and the pixel drive circuit may be as follows. For a fourth data signal line 61-4 transmitting a data signal of a green image, the fourth data signal line 61-4 extends first to a fourth circuit unit (corresponding to a green light emitting unit formed subsequently) of the Mth unit row and the (N+3)th unit column, and is connected with a pixel drive circuit in the fourth circuit unit. Then the fourth data signal line 61-4 extends to a fourth circuit unit of the (M+1)th unit row and the (N+5)th unit column, and is connected with a pixel drive circuit in the fourth circuit unit. Then the fourth data signal line 61-4 extends to a fourth circuit unit of the (M+2)th unit row and the (N+3)th unit column, and is connected with a pixel drive circuit in the fourth circuit unit. Then the fourth data signal line 61-4 extends to a fourth circuit unit of the (M+3)th unit row and the (N+5)th unit column, and is connected with a pixel drive circuit in the fourth circuit unit. Since the pixel drive circuit in the fourth circuit unit is connected with a fourth anode in a green light emitting unit formed subsequently, thereby a connection between the fourth data signal line 61-4 and a pixel drive circuit driving the green light emitting unit is achieved.

In an exemplary implementation mode, at least one of the first data signal line 61-1, the second data signal line 61-2, the third data signal line 61-3, and the fourth data signal line 61-4 includes a first line segment 61A, a second line segment 61B, a third line segment 61C, a fourth line segment 61D, and a fifth line segment 61E connected in sequence.

In an exemplary implementation mode, the first data signal line 61-1 is taken as an example. The first line segment 61A may be in a shape of a straight line or a polyline extending along the second direction Y, the first line segment 61A is provided in a circuit unit of the Mth unit row and the Nth unit column, and the first line segment 61A is connected with a pixel drive circuit in the circuit unit. The second line segment 61B may be in a shape of a straight line or a polyline extending along the first direction X, a first end of the second line segment 61B is connected with a second end of the first line segment 61A, and a second end of the second line segment 61B extends to a circuit unit of the Mth unit row and the (N+2)th unit column. The third line segment 61C may be in a shape of a straight line or a polyline extending in the second direction Y, a first end of the third line segment 61C is connected with a second end of the second line segment 61B, a second end of the third line segment 61C extends to a circuit unit of the (M+1)th unit row and the (N+2)th unit column, and the third line segment 61C is connected with a pixel drive circuit in the circuit unit. The fourth line segment 61D may be in a shape of a straight line or a polyline extending in an opposite direction of the first direction X, a first end of the fourth line segment 61D is connected with the second end of the third line segment 61C, and a second end of the fourth line segment 61D extends to a circuit unit of the (M+1)th unit row and the Nth unit column. The fifth line segment 61E may be in a shape of a straight line or a polyline extending in the second direction Y, a first end of the fifth line segment 61E is connected with the second end of the fourth line segment 61D, and a second end of the fifth line segment 61E extends to a circuit unit of the (M+2)th unit row and the Nth unit column, and is connected with the first end of the first line segment 61A in the circuit unit.

In an exemplary implementation mode, the first power supply line 62 may be in a shape of a character “S” in which a main body portion extends along the second direction Y, and the first power supply line 62 may be connected with the power supply connection block 54-1 through the twenty-second via V22. Since the power supply connection block 54-1 is connected with the fourth connection electrode 54, and the fourth connection electrode 54 is connected with the first region of the fifth active layer and the second electrode plate 72 of the storage capacitor respectively, it is achieved that the first power supply line 62 writes a first power supply signal to the first electrode of the fifth transistor T5 and the second electrode plate 72 of the storage capacitor.

In an exemplary implementation mode, in at least one circuit unit, an orthographic projection of the first power supply line 62 on the base substrate is at least partially overlapped with an orthographic projection of the first connection electrode 51 on the base substrate. Since the first connection electrode 51 serves as the first node N1 of the pixel drive circuit, a power supply line having a constant potential may effectively shield an influence of data voltage jumps and other signals on the first node N1 in the pixel drive circuit, an influence of the data voltage jumps and other signals on a potential of the first node N1 is avoided, and drive performance of the pixel drive circuit is improved.

In an exemplary implementation mode, in at least one circuit unit, an orthographic projection of the first power supply line 62 on the base substrate is at least partially overlapped with an orthographic projection of the first active layer on the base substrate, the orthographic projection of the first power supply line 62 on the base substrate is at least partially overlapped with an orthographic projection of the second active layer on the base substrate, so that the first power supply line 61 may shield an active layer of an oxide transistor, may block light emitted by a light emitting device and light reflected by a film layer from irradiating the oxide transistor, may prevent the oxide transistor from characteristic drift due to illumination, thus improving electrical characteristics of the oxide transistor.

In an exemplary implementation mode, an orthographic projection of the first power supply line 62 on the base substrate is overlapped, at least partially, with an orthographic projection of the second connection electrode 52 on the base substrate.

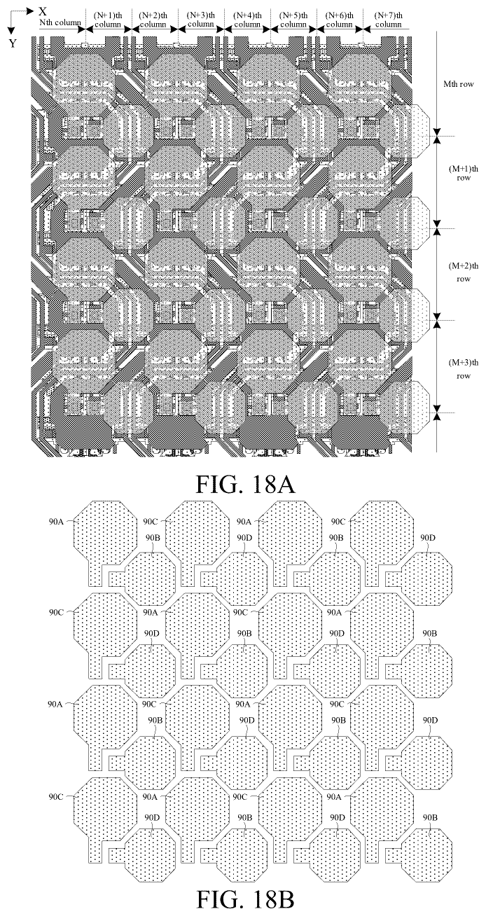

In an exemplary implementation mode, the anode connection electrode 63 may be in a shape of a block (e.g., a rectangle), the anode connection electrode 63 is connected with the fifth connection electrode 55 through the twenty-third via V23, and the anode connection electrode 63 is configured to be connected with an anode formed subsequently. Since the fifth connection electrode 55 is connected with the second region of the sixth active layer (also the second region of the seventh active layer), a connection between the anode formed subsequently and the second electrode of the sixth transistor T6 as well as the second electrode of the seventh transistor T7 may be achieved, and the pixel drive circuit may drive a light emitting device to emit light.
(10) A pattern of a second planarization layer is formed. In an exemplary implementation mode, forming the pattern of the second planarization layer may include coating a second planarization thin film on the base substrate on which the aforementioned patterns are formed, and patterning the second planarization thin film using a patterning process to form the second planarization layer covering the pattern of the fifth conductive layer, wherein a plurality of vias are provided on the second planarization layer, as shown in FIG. 17.

In an exemplary implementation mode, a plurality of vias in each circuit unit at least includes an anode via V40.

In an exemplary implementation mode, an orthographic projection of the anode via V40 on the base substrate is within a range of an orthographic projection of the anode connection electrode 63 on the base substrate, the second planarization layer within the anode via V40 is removed to expose a surface of the anode connection electrode 63, and the anode via V40 is configured such that an anode formed subsequently is connected with the anode connection electrode 63 through the via.

So far, a drive circuit layer has been prepared on the base substrate. In a plane parallel to the display substrate, the drive circuit layer may include multiple circuit units, each of the circuit units may include a pixel drive circuit, and a first scan signal line, a second scan signal line, a third scan signal line, a light emitting signal line, a first initial signal line, a second initial signal line, a data signal line, and a first power supply line connected with the pixel drive circuit. In a plane perpendicular to the display substrate, the drive circuit layer may include a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, and a second planarization layer which are arranged sequentially on the base substrate. The first semiconductor layer may include at least active layers of the third transistor to the seventh transistor. The first conductive layer may include at least a first scan signal line, a light emitting signal line, and a first electrode plate of a storage capacitor. The second conductive layer may include at least a first shielding line, a second shielding line, a first initial signal line, and a second electrode plate of the storage capacitor. The second semiconductor layer may include at least active layers of the first transistor and the second transistor. The third conductive layer may include at least a second scan signal line, a third scan signal line, and a second initial signal line. The fourth conductive layer may include at least a first initial connection line, a second initial connection line, and a plurality of connection electrodes. The fifth conductive layer may include at least a data signal line and a first power supply line.

In an exemplary implementation mode, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation mode, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, a multi-layer, or a composite layer. The first planarization layer and the second planarization layer may be made of an organic material, such as resin.

In an exemplary implementation mode, after preparation of the drive circuit layer is completed, a light emitting structure layer is prepared on the drive circuit layer, and a preparation process of the light emitting structure layer may include following operations.
(11) A pattern of an anode conductive layer is formed. In an exemplary implementation mode, forming a pattern of an anode conductive layer may include: depositing an anode conductive thin film on the base substrate where the aforementioned patterns are formed, and patterning the anode conductive thin film through a patterning process to form the anode conductive layer arranged on the second planarization layer, as shown in FIG. 18A and FIG. 18B, and FIG. 18B is a schematic plan view of the anode conductive layer in FIG. 18A.

In an exemplary implementation mode, the anode conductive layer may include a first anode 90A located in a first light emitting unit, a second anode 90B located in a second light emitting unit, a third anode 90C located in a third light emitting unit, and a fourth anode 90D located in a fourth light emitting unit. The first anode 90A, the second anode 90B, the third anode 90C, and the fourth anode 90D may be connected with anode connection electrodes 63 of circuit units in which they are located through the anode via V40, respectively.

In an exemplary implementation mode, at least one of the first anode 90A, the second anode 90B, the third anode 90C, and the fourth anode 90D may include a main body portion and a connection portion connected with each other, a shape of the main body portion may be a circular, oval, rectangular, rhombus, pentagonal, or hexagonal shape, and a shape of the connection portion may be a strip shape, a first end of the connection portion is directly connected with the main body portion, and a second end of the connection portion extends toward a direction away from the main body portion, and is connected with the anode connection electrode 63 through the anode via V40.

In an exemplary implementation mode, in the first direction X, the first anode 90A, the second anode 90B, the third anode 90C, and the fourth anode 90D may be periodically arranged in the first direction X. In the second direction Y, the first anode 90A and the third anode 90C are alternately disposed in the second direction Y, the second anode 90B and the fourth anode 90D are alternately disposed in the second direction Y, and corresponding anodes of an odd row and an even row are disposed in a staggered manner.

In an exemplary implementation mode, a first anode 90A of a red light emitting unit is connected with an anode connection electrode 63 of a first circuit unit, a second anode 90B of a first green light emitting unit is connected with an anode connection electrode 63 of a second circuit unit, a third anode 90C of a blue light emitting unit is connected with an anode connection electrode 63 of a third circuit unit, and a fourth anode 90D of a second green light emitting unit is connected with an anode connection electrode 63 of a fourth circuit unit.

In an exemplary implementation mode, an orthographic projection of a main body portion of the first anode 90A in the red light emitting unit on the base substrate is at least partially overlapped with orthographic projections of pixel drive circuits in the first circuit unit and the second circuit unit on the base substrate, an orthographic projection of a main body portion of the second anode 90B in the green light emitting unit on the base substrate is at least partially overlapped with orthographic projections of pixel drive circuits in the second circuit unit and the third circuit unit on the base substrate, an orthographic projection of a main body portion of the third anode 90C in the blue light emitting unit on the base substrate is at least partially overlapped with orthographic projections of pixel drive circuits in the third circuit unit and the fourth circuit unit on the base substrate, and an orthographic projection of a main body portion of the fourth anode 90D in the green light emitting unit on the base substrate is at least partially overlapped with orthographic projections of pixel drive circuits in the first circuit unit and the fourth circuit unit on the base substrate.

In an exemplary implementation mode, at least one first data signal line 61-1 transmitting a data signal of a red image, not only an orthographic projection of the first data signal line 61-1 on the base substrate is at least partially overlapped with orthographic projections of the first anode 90A and the third anode 90C on the base substrate, but also the orthographic projection of the first data signal line 61-1 on the base substrate is at least partially overlapped with an orthographic projection of at least one of the second anode 90B and the fourth anode 90D on the base substrate.

In an exemplary implementation mode, at least one second data signal line 61-2 transmitting a data signal of a green image, not only an orthographic projection of the second data signal line 61-2 on the base substrate is at least partially overlapped with an orthographic projection of the second anode 90B on the base substrate, but also the orthographic projection of the second data signal line 61-2 on the base substrate is at least partially overlapped with an orthographic projection of at least one of the first anode 90A and the third anode 90C on the base substrate.

In an exemplary implementation mode, at least one third data signal line 61-3 transmitting a data signal of a blue image, not only an orthographic projection of the third data signal line 61-3 on the base substrate is at least partially overlapped with orthographic projections of the first anode 90A and the third anode 90C on the base substrate, but also the orthographic projection of the third data signal line 61-3 on the base substrate is at least partially overlapped with an orthographic projection of at least one of the second anode 90B and the fourth anode 90D on the base substrate.

In an exemplary implementation mode, at least one fourth data signal line 61-4 transmitting a data signal of a green image, not only an orthographic projection of the fourth data signal line 61-4 on the base substrate is at least partially overlapped with an orthographic projection of the fourth anode 90D on the base substrate, but also the orthographic projection of the fourth data signal line 61-4 on the base substrate is at least partially overlapped with an orthographic projection of at least one of the first anode 90A and the third anode 90C on the base substrate.

In an exemplary implementation mode, in at least one circuit unit, an orthographic projection of a third line segment 61C of the first data signal line 61-1 on the base substrate is at least partially overlapped with an orthographic projection of at least one of the second anode 90B and the fourth anode 90D on the base substrate.

In an exemplary implementation mode, in at least one circuit unit, an orthographic projection of a third line segment 61C of the third data signal line 61-3 on the base substrate is at least partially overlapped with an orthographic projection of at least one of the second anode 90B and the fourth anode 90D on the base substrate.

In an exemplary implementation mode, in at least one circuit unit, an orthographic projection of a second line segment 61B of the first data signal line 61-1 on the base substrate is at least partially overlapped with an orthographic projection of the first anode 90A on the base substrate.

In an exemplary implementation mode, in at least one circuit unit, an orthographic projection of a fourth line segment 61D of the first data signal line 61-1 on the base substrate is at least partially overlapped with an orthographic projection of the third anode 90C on the base substrate.

In an exemplary implementation mode, in at least one circuit unit, an orthographic projection of a second line segment 61B of the third data signal line 61-3 on the base substrate is at least partially overlapped with an orthographic projection of the third anode 90C on the base substrate.

In an exemplary implementation mode, in at least one circuit unit, an orthographic projection of a fourth line segment 61D of the third data signal line 61-3 on the base substrate is at least partially overlapped with an orthographic projection of the first anode 90A on the base substrate.

In an exemplary implementation mode, in at least one circuit unit, an orthographic projection of a second line segment 61B of the second data signal line 61-2 on the base substrate is at least partially overlapped with an orthographic projection of the third anode 90C on the base substrate.

In an exemplary implementation mode, in at least one circuit unit, an orthographic projection of a fourth line segment 61D of the second data signal line 61-2 on the base substrate is at least partially overlapped with an orthographic projection of the first anode 90A on the base substrate.

In an exemplary implementation mode, in at least one circuit unit, an orthographic projection of a second line segment 61B of the fourth data signal line 61-4 on the base substrate is at least partially overlapped with an orthographic projection of the first anode 90A on the base substrate.

In an exemplary implementation mode, in at least one circuit unit, an orthographic projection of a fourth line segment 61D of the fourth data signal line 61-4 on the base substrate is at least partially overlapped with an orthographic projection of the third anode 90C on the base substrate.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, a subsequent preparation process may include forming a pattern of a pixel definition layer, a plurality of pixel openings are provided on the pixel definition layer, the plurality of pixel openings may expose surfaces of the first anode, the second anode, the third anode, and the fourth anode, respectively. subsequently, an organic emitting layer is formed using an evaporation or inkjet printing process, and a cathode is formed on the organic emitting layer, and preparation of a light emitting structure layer is completed. Subsequently, an encapsulation structure layer is formed, and the encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

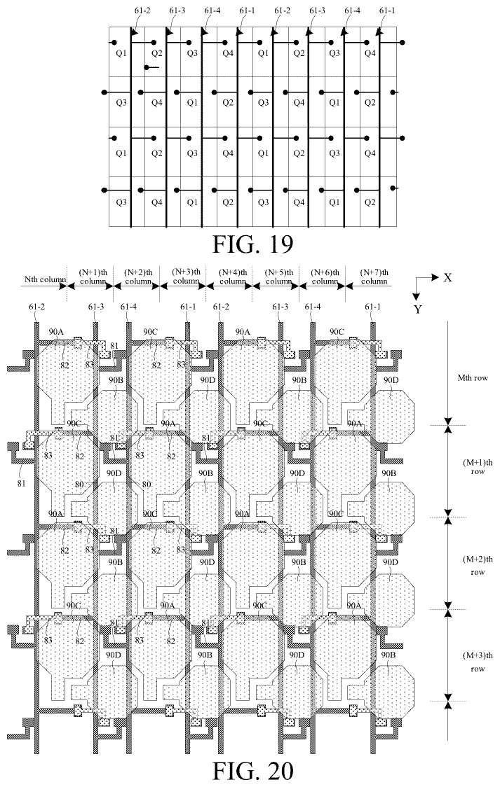

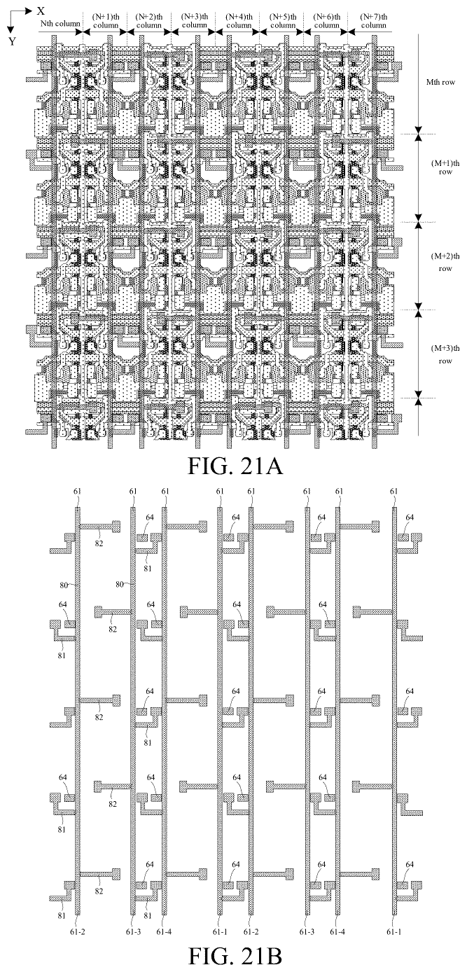

FIG. 19 is a schematic diagram showing a connection between data signal lines in another display substrate according to an exemplary embodiment of the present disclosure, and FIG. 20 is a schematic diagram showing another positional relationship between a data signal line and an anode according to an exemplary embodiment of the present disclosure. A corresponding relationship between a circuit unit and a light emitting unit in this embodiment is the same as that shown in FIGS. 5A to 5C. As shown in FIGS. 19 and 20, at least one of the first data signal line 61-1, the second data signal line 61-2, the third data signal line 61-3, and the fourth data signal line 61-4 has a dendritic shape. The first data signal line 61-1 is connected with the pixel drive circuit of the first circuit unit Q1, and the first data signal line 61-1 is a data signal line that only transmits the data signal of the red image. The second data signal line 61-2 is connected with the pixel drive circuit of the second circuit unit Q2, and the second data signal line 61-2 is a data signal line that only transmits the data signal of the green image. The third data signal line 61-3 is connected with the pixel drive circuit of the third circuit unit Q3, and the third data signal line 61-3 is a data signal line that only transmits the data signal of the blue image. The fourth data signal line 61-4 is connected with the pixel drive circuit of the fourth circuit unit Q4, and the fourth data signal line 61-4 is a data signal line that only transmits the data signal of the green image.

In an exemplary implementation mode, a main body portion of at least one of the first data signal lines 61-1, the second data signal line 61-2, the third data signal line 61-3, and the fourth data signal line 61-4 is provided in a plurality of circuit units in a unit column, and a connection mode of a data signal line and a pixel drive circuit is that in an odd unit row (e.g., an Mth unit row, an (M+2)th unit row), the data signal line is connected with a pixel drive circuit in a circuit unit of the odd unit row and a next unit column, and in an even unit row (e.g., an (M+1)th unit row, an (M+3)th unit row), the data signal line is connected with a pixel drive circuit in a circuit unit of the even unit row and a previous unit column.

In an exemplary implementation mode, at least one of the first data signal line 61-1, the second data signal line 61-2, the third data signal line 61-3, and the fourth data signal line 61-4 may include a data trace portion 80, a first transfer electrode 81, a second transfer electrode 82, and a third transfer electrode 83. The data trace portion 80 may be in a shape of a straight line or a polyline extending along the second direction Y, and the first transfer electrode 81, the second transfer electrode 82, and the third transfer electrode 83 may be in a shape of a straight line or a polyline extending along the first direction X.

In an exemplary implementation mode, the second transfer electrode 82 may be in a shape of a straight line, and the first transfer electrode 81 and the third transfer electrode 83 may be in a shape of a character “L”.

In an exemplary implementation mode, when the data trace portion 80 is provided in a plurality of circuit units of an even unit column (e.g., an (N+1)th unit column, an (N+3)th unit column, an (N+5)th unit column, and an (N+7)th unit column), the first transfer electrode 81 may be provided in an odd unit row (e.g., the Mth unit row, the (M+2)th unit row), and the second transfer electrode 82 and the third transfer electrode 83 may be provided in an even unit row (e.g., the (M+1)th unit row, the (M+3)th unit row). A first end of the first transfer electrode 81 is connected with the data trace portion 80, and a second end of the first transfer electrode 81 extends to the circuit unit of the odd unit row and the next unit column, and is connected with the pixel drive circuit in the circuit unit. A first end of the second transfer electrode 82 is connected with the data trace portion 80, a second end of the second transfer electrode 82 extends to the circuit unit of the even unit row and the previous unit column, a first end of the third transfer electrode 83 is connected with the second end of the second transfer electrode 82, and a second end of the third transfer electrode 83 is connected with the pixel drive circuit in the circuit unit.

In an exemplary implementation mode, when the data trace portion 80 is provided in a plurality of circuit units of an odd unit column (e.g., an Nth unit column, an (N+2)th unit column, an (N+4)th unit column, and an (N+6)th unit column), the first transfer electrode 81 may be provided in an even unit row (e.g., the (M+1)th unit row, the (M+3)th unit row), and the second transfer electrode 82 and the third transfer electrode 83 may be provided in an odd unit row (e.g., the Mth unit row, the (M+2)th unit row). A first end of the first transfer electrode 81 is connected with the data trace portion 80, and a second end of the first transfer electrode 81 extends to the circuit unit of the even unit row and the previous unit column, and is connected with the pixel drive circuit in the circuit unit. A first end of the second transfer electrode 82 is connected with the data trace portion 80, a second end of the second transfer electrode 82 extends to the circuit unit of the odd unit row and the next unit column, a first end of the third transfer electrode 83 is connected with the second end of the second transfer electrode 82, and a second end of the third transfer electrode 83 is connected with the pixel drive circuit in the circuit unit.

In an exemplary implementation mode, in a direction perpendicular to the base substrate, the drive structure layer includes a plurality of conductive layers, the data trace portion 80, the first transfer electrode 81, and the second transfer electrode 82 may be disposed in a same conductive layer, and the second transfer electrode 82 and the third transfer electrode 83 may be disposed in different conductive layers.

In an exemplary implementation mode, the data trace portion 80, the first transfer electrode 81, and the second transfer electrode 82 may be of an interconnected integral structure, and the third transfer electrode 83 may be connected with the second transfer electrode 82 through a via.

In an exemplary implementation mode, an orthographic projection of at least one third transfer electrode 83 on the base substrate is at least partially overlapped with an orthographic projection of at least one data trace portion 80 on the base substrate.

In an exemplary implementation mode, an orthographic projection of a data trace portion 80 of the first data signal line 61-1 on the base substrate is at least partially overlapped with an orthographic projection of at least one of the second anode 90B and the fourth anode 90D on the base substrate.

In an exemplary implementation mode, an orthographic projection of data trace portion 80 of the third data signal line 61-3 on the base substrate is at least partially overlapped with an orthographic projection of at least one of the second anode 90B and the fourth anode 90D on the base substrate.

In an exemplary implementation mode, a preparation process of the display substrate according to this embodiment may include following operations.
(21) A pattern of a first semiconductor layer is formed. In an exemplary implementation mode, a process of forming the first semiconductor layer and a formed first semiconductor layer are substantially the same as those shown in FIG. 8 above.
(22) A pattern of a first conductive layer is formed. In an exemplary implementation mode, a process of forming the first conductive layer and a formed first conductive layer are substantially the same as those shown in FIGS. 9A and 9B above.
(23) A pattern of a second conductive layer is formed. In an exemplary implementation mode, a process of forming the second conductive layer and a formed second conductive layer are substantially the same as those shown in FIGS. 10A and 10B above.
(24) A pattern of a second semiconductor layer is formed. In an exemplary implementation mode, a process of forming the second semiconductor layer and a formed second semiconductor layer are substantially the same as those shown in FIGS. 11A and 11B above.
(25) A pattern of a third conductive layer is formed. In an exemplary implementation mode, a process of forming the third conductive layer and a formed third conductive layer are substantially the same as those shown in FIGS. 12A and 12B above.
(26) A pattern of a sixth insulation layer is formed. In an exemplary implementation mode, a process of forming the sixth insulation layer and a plurality of vias formed are substantially the same as those shown in FIG. 13 above.
(27) A pattern of a fourth conductive layer is formed. In an exemplary implementation mode, a process of forming the fourth conductive layer and a formed fourth conductive layer are substantially the same as those shown in FIGS. 14A, 14B, and 14C above.
(28) A pattern of a first planarization layer is formed. In an exemplary implementation mode, a process of forming the first planarization layer and a plurality of vias formed are substantially the same as those shown in FIG. 15 above.
(29) A pattern of a fifth conductive layer is formed. In an exemplary implementation mode, forming the pattern of the fifth conductive layer may include: depositing a fifth conductive thin film on the base substrate on which the above-mentioned patterns are formed, and patterning the fifth conductive thin film using a patterning process to form the fifth conductive layer disposed on the first planarization layer, as shown in FIG. 21A and FIG. 21B, and FIG. 21B is a schematic plan view of the fifth conductive layer in FIG. 21A.

In an exemplary implementation mode, a fifth conductive layer of each circuit unit may include at least a data signal line 61.

In an exemplary implementation mode, the data signal line 61 may be in a dendritic shape in which a main body portion extends along the second direction Y, and the data signal line 61 is connected with the third connection electrode 53 through the twenty-first via V21, achieving that the data signal line 61 writes a data signal to the first electrode of the fourth transistor T4.

In an exemplary implementation mode, the data signal line 61 may include a first data signal line 61-1, a second data signal line 61-2, a third data signal line 61-3, and a fourth data signal line 61-4, the first data signal line 61-1, the second data signal line 61-2, the third data signal line 61-3, and the fourth data signal line 61-4 may be arranged periodically in the first direction X, and each data signal line is connected with a pixel drive circuit that drives a same color.

In an exemplary implementation mode, at least one data signal line 61 may include a data trace portion 80, a first transfer electrode 81, and a second transfer electrode 82. The data trace portion 80 may be in a shape of a straight line or a polyline in which a main body portion extends along the second direction Y, and may be disposed in a corresponding unit column. The first transfer electrode 81 may be in a shape of a character “L” and may be provided on a side of the data trace portion 80. A first end of the first transfer electrode 81 is connected with the data trace portion 80, and a second end of the first transfer electrode 81 is connected with the third connection electrode 53 through the twenty-first via V21. The second transfer electrode 82 may be in a shape of a straight line or a polyline in which a main body portion extends along the first direction X, and may be provided on the other side of the data trace portion 80. A first end of the second transfer electrode 82 is connected with the data trace portion 80, a second end of the second transfer electrode 82 extends toward a direction away from the data trace portion 80, and a second end of the second transfer electrode 82 is configured to be connected with a third transfer electrode formed subsequently.

In an exemplary implementation mode, a connection mode between a data signal line and a pixel drive circuit is as follows.

In an exemplary implementation mode, for a first data signal line 61-1 that transmits a data signal of a red image, a data trace portion 80 of the first data signal line 61-1 may be provided in an (N+3)th unit column (even unit column). A first transfer electrode 81 of the first data signal line 61-1 may be provided in circuit units of the Mth unit row and the (M+2)th unit row (odd unit row), the first transfer electrode 81 may be provided on one side of the data trace portion 80 in the first direction X, a first end of the first transfer electrode 81 is connected with the data trace portion 80, and a second end of the first transfer electrode 81 extends to a circuit unit of a current unit row and the (N+4)th unit column, and is connected with a third connection electrode 53 in the circuit unit. A second transfer electrode 82 of the first data signal line 61-1 may be provided in circuit units of the (M+1)th unit row and the (M+3)th unit row (even unit row), the second transfer electrode 82 may be provided in one side of the data trace portion 80 in an opposite direction of the first direction X, a first end of the second transfer electrode 82 is connected with the data trace portion 80, a second end of the second transfer electrode 82 extends to a circuit unit of a current unit row and the (N+2)th unit column, and a second end of the second transfer electrode 82 is configured to be connected with a third transfer electrode formed subsequently, and is connected with a third connection electrode 53 in the circuit unit of the current unit row and the (N+2)th unit column through the third transfer electrode. Since a circuit unit of the Mth unit row and the (N+4)th unit column, a circuit unit of the (M+1)th unit row and the (N+2)th unit column, a circuit unit of the (M+2)th unit row and the (N+4)th unit column, and a circuit unit of the (M+3)th unit row and the (N+2)th unit column are all first circuit units, a connection between the first data signal line 61-1 and a pixel drive circuit driving a red light emitting unit is achieved.

In an exemplary implementation mode, for a second data signal line 61-2 that transmits a data signal of a green image, a data trace portion 80 of the second data signal line 61-2 may be provided in a plurality of circuit units of the (N+4)th unit column (odd unit column). A second transfer electrode 82 of the second data signal line 61-2 may be provided in circuit units of the Mth unit row and the (M+2)th unit row (odd unit row), the second transfer electrode 82 may be provided in one side of the data trace portion 80 in the first direction X, a first end of the second transfer electrode 82 is connected with the data trace portion 80, a second end of the second transfer electrode 82 extends to a circuit unit of a current unit row and the (N+5)th unit column, and a second end of the second transfer electrode 82 is configured to be connected with a third transfer electrode formed subsequently, and is connected with a third connection electrode 53 in the circuit unit of the current unit row and the (N+5)th unit column through the third transfer electrode. A first transfer electrode 81 of the second data signal line 61-2 may be provided in circuit units of the (M+1)th unit row and the (M+3)th unit row (even unit row), the first transfer electrode 81 may be provided on one side of the data trace portion 80 in an opposite direction of the first direction X, a first end of the first transfer electrode 81 is connected with the data trace portion 80, and a second end of the first transfer electrode 81 extends to a circuit unit of a current unit row and the (N+3)th unit column, and is connected with a third connection electrode 53 in the circuit unit. Since a circuit unit of the Mth unit row and the (N+5)th unit column, a circuit unit of the (M+1)th unit row and the (N+3)th unit column, a circuit unit of the (M+2)th unit row and the (N+5)th unit column, and a circuit unit of the (M+3)th unit row and the (N+3)th unit column are all second circuit units, a connection between the second data signal line 61-2 and a pixel drive circuit driving a green light emitting unit is achieved.

In an exemplary implementation mode, for a third data signal line 61-3 that transmits a data signal of a blue image, a data trace portion 80 of the third data signal line 61-3 is provided in a plurality of circuit units of the (N+1)th unit column (even unit column). A first transfer electrode 81 of the third data signal line 61-3 may be provided in circuit units of the Mth unit row and the (M+2)th unit row (odd unit row), the first transfer electrode 81 may be provided on one side of the data trace portion 80 in the first direction X, a first end of the first transfer electrode 81 is connected with the data trace portion 80, and a second end of the first transfer electrode 81 extends to a circuit unit of a current unit row and the (N+2)th unit column, and is connected with a third connection electrode 53 in the circuit unit. A second transfer electrode 82 of the third data signal line 61-3 may be provided in circuit units of the (M+1)th unit row and the (M+3)th unit row (even unit row), the second transfer electrode 82 may be provided in one side of the data trace portion 80 in an opposite direction of the first direction X, a first end of the second transfer electrode 82 is connected with the data trace portion 80, a second end of the second transfer electrode 82 extends to a circuit unit of a current unit row and the Nth unit column, and a second end of the second transfer electrode 82 is configured to be connected with a third transfer electrode formed subsequently, and is connected with a third connection electrode 53 in the circuit unit of the current unit row and the Nth unit column through the third transfer electrode. Since a circuit unit of the Mth unit row and the (N+2)th unit column, a circuit unit of the (M+1)th unit row and the Nth unit column, a circuit unit of the (M+2)th unit row and the (N+2)th unit column, and a circuit unit of the (M+3)th unit row and the Nth unit column are all third circuit units, a connection between the third data signal line 61-3 and a pixel drive circuit driving a blue light emitting unit is achieved.

In an exemplary implementation mode, for a fourth data signal line 61-4 that transmits a data signal of a green image, a data trace portion 80 of the fourth data signal line 61-4 may be provided in a plurality of circuit units of the (N+2)th unit column (odd unit column). A second transfer electrode 82 of the fourth data signal line 61-4 may be provided in circuit units of the Mth unit row and the (M+2)th unit row (odd unit row), the second transfer electrode 82 may be provided in one side of the data trace portion 80 in the first direction X, a first end of the second transfer electrode 82 is connected with the data trace portion 80, a second end of the second transfer electrode 82 extends to a circuit unit of a current unit row and the (N+3)th unit column, and a second end of the second transfer electrode 82 is configured to be connected with a third transfer electrode formed subsequently, and is connected with a third connection electrode 53 in the circuit unit of the current unit row and the (N+3)th unit column through the third transfer electrode. A first transfer electrode 81 of the fourth data signal line 61-4 may be provided in circuit units of the (M+1)th unit row and the (M+3)th unit row (even unit row), the first transfer electrode 81 may be provided on one side of the data trace portion 80 in an opposite direction of the first direction X, a first end of the first transfer electrode 81 is connected with the data trace portion 80, and a second end of the first transfer electrode 81 extends to a circuit unit of a current unit row and the (N+1)th unit column, and is connected with a third connection electrode 53 in the circuit unit. Since a circuit unit of the Mth unit row and the (N+3)th unit column, a circuit unit of the (M+1)th unit row and the (N+1)th unit column, a circuit unit of the (M+2)th unit row and the (N+3)th unit column, and a circuit unit of the (M+3)th unit row and the (N+1)th unit column are all fourth circuit units, a connection between the fourth data signal line 61-4 and a pixel drive circuit driving a green light emitting unit is achieved.

In an exemplary implementation mode, a data trace portion 80, a first transfer electrode 81, and a second transfer electrode 82 in at least one data signal line are of an interconnected integral structure.

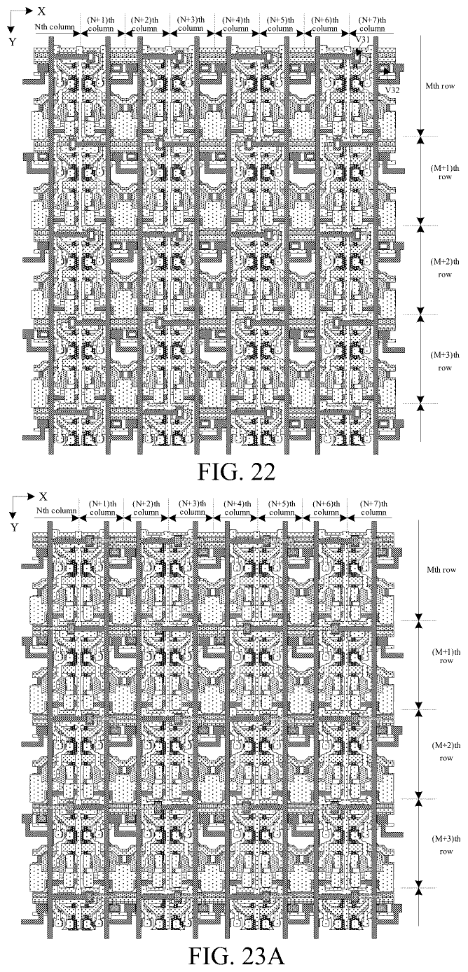

In an exemplary implementation mode, the fifth conductive layer may further include an eleven connection electrode 64. The eleventh connection electrode 64 may have a block shape (e.g., a rectangle) and may be provided in some circuit units. The eleventh connection electrode 64 is connected with the third connection electrode 53 through the twenty-first via V21. In an exemplary implementation mode, the eleventh connection electrode 64 is configured to be connected with a third transfer electrode formed subsequently.
(30) A pattern of a second planarization layer is formed. In an exemplary implementation mode, forming the pattern of the second planarization layer may include coating a second planarization thin film on the base substrate on which the aforementioned patterns are formed, and patterning the second planarization thin film using a patterning process to form the second planarization layer covering the pattern of the fifth conductive layer, wherein a plurality of vias are provided on the second planarization layer, as shown in FIG. 22.

In an exemplary implementation mode, a plurality of vias in some circuit units may include a thirty-first via V31 and a thirty-second via V32.

In an exemplary implementation mode, an orthographic projection of the thirty-first via V31 on the base substrate is within a range of an orthographic projection of the second transfer electrode 82 on the base substrate, the second planarization layer within the thirty-first via V31 is removed to expose a surface of the second end of the second transfer electrode 82, and the thirty-first via V31 is configured such that a thirty transfer electrode formed subsequently is connected with the second end of the second transfer electrode 82 through the via.

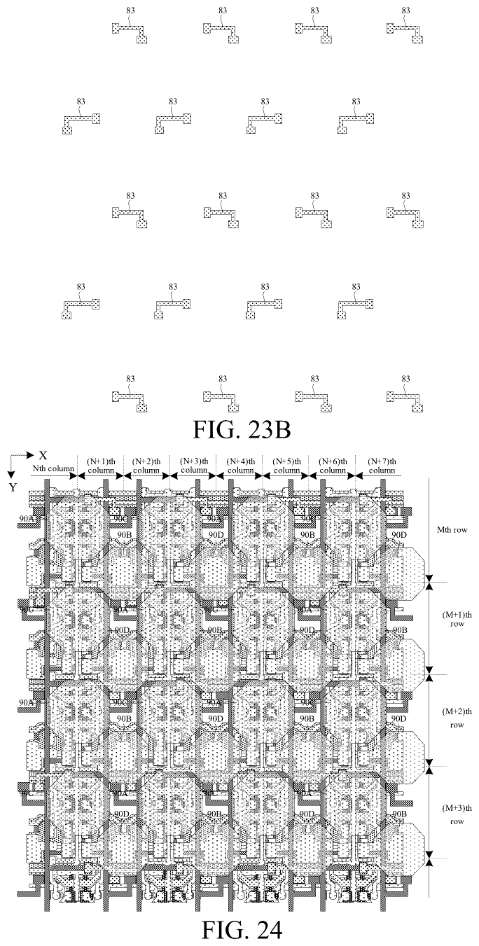

In an exemplary implementation mode, an orthographic projection of the thirty-second via V32 on the base substrate is located within a range of an orthographic projection of the eleven connection electrode 64 on the base substrate, the second planarization layer within the thirty-second via V32 is removed to expose a surface of the eleven connection electrode 64, and the thirty-second via V32 is configured such that a third transfer electrode formed subsequently is connected with the eleven connection electrode 64 through the via.
(31) A pattern of a sixth conductive layer is formed. In an exemplary implementation mode, forming a sixth conductive layer may include: depositing a sixth conductive thin film on the base substrate on which the aforementioned patterns are formed, and patterning the sixth conductive thin film using a patterning process to form a sixth conductive layer disposed on the second planarization layer, as shown in FIG. 23A and FIG. 23B, and FIG. 23B is a schematic plan view of the sixth conductive layer in FIG. 23A. In an exemplary implementation mode, the sixth conductive layer may be referred to as a third source-drain metal (SD3) layer.

In an exemplary implementation mode, the sixth conductive layer of some circuit units includes at least a third transfer electrode 83.

In an exemplary implementation mode, the third transfer electrode 83 may be in a shape of a character “L”, a first end of the third transfer electrode 83 is connected with the second end of the second transfer electrode 82 through the thirty-first via V31, and a second end of the third transfer electrode 83 is connected with the eleventh connection electrode 64 through the thirty-second via V32. Since the eleventh connection electrode 64 is connected with the third connection electrode 53 through a via, it is achieved that the data signal line 61 writes a data signal to the first electrode of the fourth transistor T4

In an exemplary implementation mode, an orthographic projection of at least one third transfer electrode 83 on the base substrate is at least partially overlapped with an orthographic projection of the at least one data trace portion 80 on the base substrate.

In an exemplary implementation mode, the fifth conductive layer of each circuit unit may further include a first power supply line connected with the fourth connection electrode 54 through a via and a first anode connection electrode connected with the fifth connection electrode 55 through a via. The sixth conductive layer of each circuit unit may further include a second anode connection electrode connected with the first anode connection electrode through a via, which will not be repeated here.
(32) A pattern of a third planarization layer is formed. In an exemplary implementation mode, forming the pattern of the third planarization layer may include: coating a third planarization thin film on the base substrate on which the aforementioned patterns are formed, and patterning the third planarization thin film through a patterning process to form the third planarization layer that covers the pattern of the sixth conductive layer, wherein the third planarization layer is provided with an anode via, and the anode via exposes a surface of the second anode connection electrode.

So far, a drive circuit layer has been prepared on the base substrate. A structure of the drive circuit layer in the present embodiment is substantially the same as that of the foregoing embodiment except that the drive circuit layer further includes the sixth conductive layer and the third planarization layer.

In an exemplary implementation mode, after preparation of the drive circuit layer is completed, a light emitting structure layer is prepared on the drive circuit layer, and a preparation process of the light emitting structure layer may include following operations.
(33) A pattern of an anode conductive layer is formed. In an exemplary implementation mode, forming the pattern of the anode conductive layer may include depositing an anode conductive thin film on the base substrate on which the above-mentioned patterns are formed, and patterning the anode conductive thin film using a patterning process to form the anode conductive layer disposed on the third planarization layer, as shown in FIG. 24.

In an exemplary implementation mode, the anode conductive layer may include a first anode 90A, a second anode 90B, a third anode 90C, and a fourth anode 90D, and positions, shapes, and connection structures of the above anodes are substantially the same as those shown in FIGS. 18A and 18B above.

In an exemplary implementation mode, in at least one circuit unit, an orthographic projection of a main body portion of a first anode 90A in a red light emitting unit on the base substrate is at least partially overlapped with orthographic projections of pixel drive circuits in the first circuit unit and the second circuit unit on the base substrate. In at least one circuit unit, an orthographic projection of a main body portion of a second anode 90B in a green light emitting unit on the base substrate is at least partially overlapped with orthographic projections of pixel drive circuits in the second circuit unit and the third circuit unit on the base substrate. In at least one circuit unit, an orthographic projection of a main body portion of a third anode 90C in a blue light emitting unit on the base substrate is at least partially overlapped with orthographic projections of pixel drive circuits in the third circuit unit and the fourth circuit unit on the base substrate. In at least one circuit unit, an orthographic projection of a main body portion of a first anode 90D in a green light emitting unit on the base substrate is at least partially overlapped with orthographic projections of pixel drive circuits in the first circuit unit and the fourth circuit unit on the base substrate.

In an exemplary implementation mode, in at least one circuit unit, at least one first data signal line 61-1 transmitting a data signal of a red image, not only an orthographic projection of the first data signal line 61-1 on the base substrate is at least partially overlapped with orthographic projections of the first anode 90A and the third anode 90C on the base substrate, but also the orthographic projection of the first data signal line 61-1 on the base substrate is at least partially overlapped with an orthographic projection of at least one of the second anode 90B and the fourth anode 90D on the base substrate.

In an exemplary implementation mode, in at least one circuit unit, at least one second data signal line 61-2 transmitting a data signal of a green image, not only an orthographic projection of the second data signal line 61-2 on the base substrate is at least partially overlapped with an orthographic projection of the second anode 90B on the base substrate, but also the orthographic projection of the second data signal line 61-2 on the base substrate is at least partially overlapped with an orthographic projection of at least one of the first anode 90A and the third anode 90C on the base substrate.

In an exemplary implementation mode, in at least one circuit unit, at least one third data signal line 61-3 transmitting a data signal of a blue image, not only an orthographic projection of the third data signal line 61-3 on the base substrate is at least partially overlapped with orthographic projections of the first anode 90A and the third anode 90C on the base substrate, but also the orthographic projection of the third data signal line 61-3 on the base substrate is at least partially overlapped with an orthographic projection of at least one of the second anode 90B and the fourth anode 90D on the base substrate.

In an exemplary implementation mode, in at least one circuit unit, at least one fourth data signal line 61-4 transmitting a data signal of a green image, not only an orthographic projection of the fourth data signal line 61-4 on the base substrate is at least partially overlapped with an orthographic projection of the fourth anode 90D on the base substrate, but also the orthographic projection of the fourth data signal line 61-4 on the base substrate is at least partially overlapped with an orthographic projection of at least one of the first anode 90A and the third anode 90C on the base substrate.

In an exemplary implementation mode, an orthographic projection of a data trace portion 80 of the first data signal line 61-1 on the base substrate is at least partially overlapped with an orthographic projection of at least one of the second anode 90B and the fourth anode 90D on the base substrate.

In an exemplary implementation mode, an orthographic projection of data trace portion 80 of the third data signal line 61-3 on the base substrate is at least partially overlapped with an orthographic projection of at least one of the second anode 90B and the fourth anode 90D on the base substrate.

In an exemplary implementation mode, in at least one circuit unit, an orthographic projection of the second transfer electrode 82 on the base substrate is at least partially overlapped with an orthographic projection of the first anode 90A on the base substrate. In at least one circuit unit, an orthographic projection of the second transfer electrode 82 on the base substrate is at least partially overlapped with an orthographic projection of the second anode 90B on the base substrate. In at least one circuit unit, the orthographic projection of the second transfer electrode 82 on the base substrate is at least partially overlapped with an orthographic projection of the third anode 90C on the base substrate. In at least one circuit unit, the orthographic projection of the second transfer electrode 82 on the base substrate is at least partially overlapped with an orthographic projection of the fourth anode 90A on the base substrate.

In an exemplary implementation mode, in at least one circuit unit, an orthographic projection of the third transfer electrode 85 on the base substrate is at least partially overlapped with an orthographic projection of the first anode 90A on the base substrate. In at least one circuit unit, the orthographic projection of the third transfer electrode 85 on the base substrate is at least partially overlapped with an orthographic projection of the second anode 90B on the base substrate. In at least one circuit unit, the orthographic projection of the third transfer electrode 85 on the base substrate is at least partially overlapped with an orthographic projection of the third anode 90C on the base substrate. In at least one circuit unit, the orthographic projection of the third transfer electrode 85 on the base substrate is at least partially overlapped with an orthographic projection of the fourth anode 90D on the base substrate.

In an exemplary implementation mode, a subsequent preparation process may include forming a pixel definition layer, an organic emitting layer, and a cathode to complete preparation of a light emitting structure layer. Subsequently, an encapsulation structure layer is formed, which will not be repeated here.

In a display substrate in which an RGBG pixel arrangement is adopted, a single data signal line is respectively connected with a plurality of pixel drive circuits driving red light emitting units and a plurality of pixel drive circuits driving blue light emitting units in a unit column. After research, it is found that when a red image is displayed, a data signal output from the data signal line is converted at high frequency between a high potential signal and a low potential signal. When a blue image is displayed, a data signal outputted by the data signal line is also converted at high frequency between the high potential signal and the low potential signal. Due to high frequency conversion between the high potential signal and the low potential signal, power consumption of a data driver increases, thereby increasing e overall power consumption of a display apparatus.

The display substrate provided by the exemplary embodiment of the present disclosure may effectively reduce power consumption of the display apparatus by disposing a same data signal line connected with a pixel drive circuit driving a same color. Different from a linear shape of an existing data signal line, a data signal line of the display substrate of the present disclosure may be in a shape of a character “S” or a dendritic shape. A first data signal line transmitting a data signal of a red image is connected with a pixel drive circuit driving a red light emitting unit, a third data signal line transmitting a data signal of a blue image is connected with a pixel drive circuit driving a blue light emitting unit, and a second data signal line and a fourth data signal line transmitting a data signal of a green image are connected with a pixel drive circuit driving a green light emitting unit. Without changing existing driving logic, when the red image or the blue image is displayed, a data signal output by a data signal line may be a continuous high potential signal or low potential signal, thus avoiding high frequency conversion of the data signal between the high potential signal and the low potential signal, effectively reducing the increase of the power consumption of the data driver, and thus reducing the overall power consumption of the display apparatus. Simulation results show that the power consumption of the data driver may be reduced by 30% to 40% when displaying a red image. When displaying a blue image, the power consumption of the data driver may be reduced by 40% to 50%. When displaying a white image, the power consumption of the data driver may be reduced by 10% to 20%.

The display substrate of the present disclosure may effectively shield an influence of a data voltage jump and other signals on a first node in a pixel drive circuit by disposing an orthographic projection of a first power supply line on the base substrate to be at least partially overlapped with an orthographic projection of the first node of the pixel drive circuit on the base substrate, thereby avoiding an influence of data voltage jump and other signals on a potential of the first node, and effectively avoiding deterioration of crosstalk. In the display substrate of the present disclosure, by disposing an orthographic projection of a first power supply line on the base substrate to be at least partially overlapped with an orthographic projection of an oxide transistor on the base substrate, light emitted by a light emitting device and light reflected by a film layer may be blocked from irradiating the oxide transistor, the oxide transistor may be prevented from characteristic drift due to illumination, and electrical characteristics of the oxide transistor may be improved.

The preparation process of the display substrate of the present disclosure may be compatible well with an existing preparation process, is simple in process implementation, is easy to implement, and has a high production efficiency, a low production cost, and a high yield.

The structure shown and mentioned above in the present disclosure and the preparation process therefor are merely for exemplary description. In an exemplary implementation mode, corresponding structures may be altered and patterning processes may be added or reduced according to actual needs. For example, since an S-shaped data signal line provided across in a plurality of unit columns, a plurality of dummy unit columns may be provided in a frame region to ensure integrity of a data signal line at an edge position of a display region, which is not limited here in the present disclosure.

In an exemplary implementation mode, the display substrate of the present disclosure may be applied to other display apparatuses having a pixel drive circuit, such as quantum dot display, which is not limited here in the present disclosure.

The present disclosure also provides a preparation method of a display substrate, for preparing the display substrate according to the foregoing embodiments. In an exemplary implementation mode, the preparation method may include: forming a drive structure layer on a base substrate, wherein the drive structure layer includes a plurality of circuit units, and a circuit unit includes at least a pixel drive circuit, the plurality of circuit units include at least a first circuit unit, a second circuit unit, a third circuit unit, and a fourth circuit unit, the drive structure layer further at least includes a first data signal line, a second data signal line, a third data signal line, and a fourth data signal line, the first data signal line is connected with a pixel drive circuit in the first circuit unit, the second data signal line is connected with a pixel drive circuit in the second circuit unit, the third data signal line is connected with a pixel drive circuit in the third circuit unit, and the fourth data signal line is connected with a pixel drive circuit in the fourth circuit unit; forming a light emitting structure layer on the drive structure layer, wherein the light emitting structure layer includes a plurality of light emitting units, a light emitting unit includes at least an anode, the plurality of light emitting units include at least a first light emitting unit emitting red light, a third light emitting unit emitting blue light, and a second light emitting unit and a fourth light emitting unit emitting green light, the first light emitting unit, the second light emitting unit, the third light emitting unit, and the fourth light emitting unit are periodically arranged in a first direction, the first light emitting unit and the third light emitting unit are alternately arranged in a second direction, the second light emitting unit and the fourth light emitting unit are alternately arranged in the second direction, and the first direction and the second direction intersect, the first light emitting unit at least includes a first anode, the second light emitting unit at least includes a second anode, the third light emitting unit at least includes a third anode, and the fourth light emitting unit at least includes a fourth anode, the first anode is connected with the pixel drive circuit in the first circuit unit, the second anode is connected with the pixel drive circuit in the second circuit unit, the third anode is connected with the pixel drive circuit in the third circuit unit, and the fourth anode is connected with the pixel drive circuit in the fourth circuit unit; and an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present disclosure.

Although implementation modes disclosed in the present disclosure are as above, it should be noted that the above implementation modes are exemplary only rather than restrictive. Therefore, the present disclosure is not limited to what is specifically shown and described herein. Various modifications, substitutions, or omissions may be made in forms and details of implementation without departing from the scope of the present disclosure.

1. A display substrate, comprising a drive structure layer disposed on a base substrate and a light emitting structure layer disposed on a side of the drive structure layer away from the base substrate, wherein the drive structure layer comprises a plurality of circuit units, the circuit unit at least comprise pixel drive circuits, the light emitting structure layer comprises a plurality of light emitting units, the light emitting units at least comprise anodes; the plurality of light emitting units at least comprise a first light emitting unit emitting red light, a third light emitting unit emitting blue light, and a second light emitting unit and a fourth light emitting unit emitting green light, the first light emitting unit, the second light emitting unit, the third light emitting unit, and the fourth light emitting unit are periodically arranged in a first direction, the first light emitting unit and the third light emitting unit are alternately arranged in a second direction, the second light emitting unit and the fourth light emitting unit are alternately arranged in the second direction, the first direction and the second direction intersect; the first light emitting unit at least comprises a first anode, the second light emitting unit at least comprises a second anode, the third light emitting unit at least comprises a third anode, and the fourth light emitting unit at least comprises a fourth anode; the plurality of circuit units at least comprise a first circuit unit, a second circuit unit, a third circuit unit, and a fourth circuit unit, wherein a pixel drive circuit in the first circuit unit is connected with the first anode, a pixel drive circuit in the second circuit unit is connected with the second anode, a pixel drive circuit in the third circuit unit is connected with the third anode, and a pixel drive circuit in the fourth circuit unit is connected with the fourth anode; the drive structure layer further comprises at least a first data signal line, a second data signal line, a third data signal line, and a fourth data signal line, the first data signal line is connected with the pixel drive circuit in the first circuit unit, the second data signal line is connected with the pixel drive circuit in the second circuit unit, the third data signal line is connected with the pixel drive circuit in the third circuit unit, and the fourth data signal line is connected with the pixel drive circuit in the fourth circuit unit; and an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

2. The display substrate according to claim 1, wherein at least one of the first data signal line, the second data signal line, the third data signal line, and the fourth data signal line is in a shape of a character “S”.

3. The display substrate according to claim 2, wherein the at least one of the first data signal line, the second data signal line, the third data signal line and the fourth data signal line is connected with a pixel drive circuit in a following connection mode: being connected with a pixel drive circuit in a circuit unit of an Mth unit row and an Nth unit column, being connected with a pixel drive circuit in a circuit unit of an (M+1)th unit row and an (N+2)th unit column, being connected with a pixel drive circuit in a circuit unit of an (M+2)th unit row and an Nth unit column, and being connected with a pixel drive circuit in a circuit unit of an (M+3)th unit row and an (N+2)th unit column; and M and N are positive integers greater than or equal to 1.

4. The display substrate according to claim 3, wherein the at least one of the first data signal line, the second data signal line, the third data signal line, and the fourth data signal line comprises a first line segment, a second line segment, a third line segment, a fourth line segment, and a fifth line segment connected in sequence; wherein the first line segment has a straight line shape or a polyline shape extending along the second direction, the first line segment is disposed in the circuit unit of the Mth unit row and the Nth unit column, and the first line segment is connected with the pixel drive circuit in the circuit unit; the second line segment has a straight line shape or a polyline shape extending along the first direction, a first end of the second line segment is connected with a second end of the first line segment, and a second end of the second line segment extends to a circuit unit of the Mth unit row and the (N+2)th unit column; the third line segment has a straight line shape or a polyline shape extending along the second direction, a first end of the third line segment is connected with the second end of the second line segment, a second end of the third line segment extends to the circuit unit of the (M+1)th unit row and the (N+2)th unit column, and the third line segment is connected with the pixel drive circuit in the circuit unit; the fourth line segment has a straight line shape or a polyline shape extending along an opposite direction of the first direction, a first end of the fourth line segment is connected with the second end of the third line segment, and a second end of the fourth line segment extends to a circuit unit of the (M+1)th unit row and the Nth unit column; and the fifth line segment has a straight line shape or a polyline shape extending along the second direction, a first end of the fifth line segment is connected with the second end of the fourth line segment, and a second end of the fifth line segment extends to the circuit unit of the (M+2)th unit row and the Nth unit column, and is connected with a first end of a first line segment in the circuit unit.

5. The display substrate according to claim 4, wherein in at least one circuit unit, an orthographic projection of a third line segment of the first data signal line on the base substrate is at least partially overlapped with the orthographic projection of at least one of the second anode and the fourth anode on the base substrate, and/or, in at least one circuit unit, an orthographic projection of a third line segment of the third data signal line on the base substrate is at least partially overlapped with the orthographic projection of at least one of the second anode and the fourth anode on the base substrate.

6. The display substrate according to claim 4, wherein in at least one circuit unit, an orthographic projection of a second line segment of the first data signal line on the base substrate is at least partially overlapped with an orthographic projection of the first anode on the base substrate, and/or, in at least one circuit unit, an orthographic projection of a fourth line segment of the first data signal line on the base substrate is at least partially overlapped with an orthographic projection of the third anode on the base substrate, and/or, in at least one circuit unit, an orthographic projection of a second line segment of the third data signal line on the base substrate is at least partially overlapped with an orthographic projection of the third anode on the base substrate, and/or, in at least one circuit unit, an orthographic projection of a fourth line segment of the third data signal line on the base substrate is at least partially overlapped with an orthographic projection of the first anode on the base substrate.

7. The display substrate according to claim 4, wherein in at least one circuit unit, an orthographic projection of a second line segment of the second data signal line on the in base substrate is at least partially overlapped with an orthographic projection of the third anode on the base substrate, and/or, in at least one circuit unit, an orthographic projection of a fourth line segment of the second data signal line on the base substrate is at least partially overlapped with an orthographic projection of the first anode on the base substrate, and/or, in at least one circuit unit, an orthographic projection of a second line segment of the fourth data signal line on the base substrate is at least partially overlapped with an orthographic projection of the first anode on the base substrate, and/or, in at least one circuit unit, an orthographic projection of a fourth line segment of the fourth data signal line on the base substrate is at least partially overlapped with an orthographic projection of the third anode on the base substrate.

8. The display substrate according to claim 1, wherein at least one of the first data signal line, the second data signal line, the third data signal line, and the fourth data signal line has a dendritic shape.

9. The display substrate according to claim 8, wherein a plurality of unit rows and a plurality of unit columns are formed by the plurality of circuit units, a main body portion of the at least one of the first data signal line, the second data signal line, the third data signal line, and the fourth data signal line is disposed in a plurality of circuit units of one unit column, and a connection mode of the data signal line and a pixel drive circuit is that in an odd unit row, the data signal line is connected with a pixel drive circuit in a circuit unit of the odd unit row and a next unit column, and in an even unit row, the data signal line is connected with a pixel drive circuit in a circuit unit of the even unit row and a previous unit column.

10. The display substrate according to claim 9, wherein the at least one of the first data signal line, the second data signal line, the third data signal line, and the fourth data signal line comprises a data trace portion and a first transfer electrode; wherein the data trace portion has a straight line shape or a polyline shape in which a main body portion extends along the second direction, and the data trace portion is disposed in a plurality of circuit units in an even unit column; and the first transfer electrode has a straight line shape or a polyline shape extending along the first direction, the first transfer electrode is disposed in the odd unit row, a first end of the first transfer electrode is connected with the data trace portion, and a second end of the first transfer electrode extends to the circuit unit of the odd unit row and the next unit column, and is connected with the pixel drive circuit in the circuit unit.

11. The display substrate according to claim 10, wherein the at least one of the first data signal line, the second data signal line, the third data signal line, and the fourth data signal line further comprises a second transfer electrode and a third transfer electrode, the second transfer electrode and the third transfer electrode have a straight shape or a polyline shape extending along the first direction, the second transfer electrode and the third transfer electrode are disposed in the even unit row, a first end of the second transfer electrode is connected with the data trace portion, a second end of the second transfer electrode extends to the circuit unit of the even unit row and the previous unit column, a first end of the third transfer electrode is connected with the second end of the second transfer electrode, and a second end of the third transfer electrode is connected with the pixel drive circuit in the circuit unit.

12. The display substrate according to claim 9, wherein the at least one of the first data signal line, the second data signal line, the third data signal line, and the fourth data signal line comprises a data trace portion and a first transfer electrode; wherein the data trace portion has a straight line shape or a polyline shape in which a main body portion extends along the second direction, and the data trace portion is disposed in a plurality of circuit units in an odd unit column; and the first transfer electrode has a straight line shape or a polyline shape extending along the first direction, the first transfer electrode is disposed in the even unit row, a first end of the first transfer electrode is connected with the data trace portion, and a second end of the first transfer electrode extends to the circuit unit of the even unit row and the previous unit column, and is connected with the pixel drive circuit in the circuit unit.

13. The display substrate according to claim 12, wherein the at least one of the first data signal line, the second data signal line, the third data signal line, and the fourth data signal line further comprises a second transfer electrode and a third transfer electrode, the second transfer electrode and the third transfer electrode have a straight shape or a polyline shape extending along the first direction, the second transfer electrode and the third transfer electrode are disposed in the odd unit row, a first end of the second transfer electrode is connected with the data trace portion, a second end of the second transfer electrode extends to the circuit unit of the odd unit row and the next unit column, a first end of the third transfer electrode is connected with the second end of the second transfer electrode, and a second end of the third transfer electrode is connected with the pixel drive circuit in the circuit unit.

14. The display substrate according to claim 11, wherein in a direction perpendicular to the base substrate, the drive structure layer comprises a plurality of conductive layers, the data trace portion, the first transfer electrode, and the second transfer electrode are disposed in a same conductive layer, and the second transfer electrode and the third transfer electrode are arranged in different conductive layers.

15. The display substrate according to claim 14, wherein the data trace portion, the first transfer electrode, and the second transfer electrode are of an interconnected integral structure, and the third transfer electrode is connected with the second transfer electrode through a via.

16. The display substrate according to claim 10, wherein an orthographic projection of at least one third transfer electrode on the base substrate is at least partially overlapped with an orthographic projection of at least one data trace portion on the base substrate.

17. The display substrate according to claim 10, wherein an orthographic projection of a data trace portion of the first data signal line on the base substrate is at least partially overlapped with the orthographic projection of the at least one of the second anode and the fourth anode on the base substrate, and/or an orthographic projection of a data trace portion of the third data signal line on the base substrate is at least partially overlapped with the orthographic projection of the at least one of the second anode and the fourth anode on the base substrate.

18. A display apparatus, comprising a display substrate according to claim 1.

19. A preparation method of a display substrate, comprising:
forming a drive structure layer on a base substrate; wherein the drive structure layer comprises a plurality of circuit units, the circuit units at least comprise pixel drive circuits, the plurality of circuit units comprise at least a first circuit unit, a second circuit unit, a third circuit unit, and a fourth circuit unit; the drive structure layer further at least comprises a first data signal line, a second data signal line, a third data signal line, and a fourth data signal line, the first data signal line is connected with a pixel drive circuit in the first circuit unit, the second data signal line is connected with a pixel drive circuit in the second circuit unit, the third data signal line is connected with a pixel drive circuit in the third circuit unit, and the fourth data signal line is connected with a pixel drive circuit in the fourth circuit unit; and
forming a light emitting structure layer on the drive structure layer, wherein the light emitting structure layer comprises a plurality of light emitting units, the light emitting units at least comprise anodes; the plurality of light emitting units comprise at least a first light emitting unit emitting red light, a third light emitting unit emitting blue light, and a second light emitting unit and a fourth light emitting unit emitting green light, the first light emitting unit, the second light emitting unit, the third light emitting unit, and the fourth light emitting unit are periodically arranged in a first direction, the first light emitting unit and the third light emitting unit are alternately arranged in a second direction, the second light emitting unit and the fourth light emitting unit are alternately arranged in the second direction, the first direction and the second direction intersect; the first light emitting unit at least comprises a first anode, the second light emitting unit at least comprises a second anode, the third light emitting unit at least comprises a third anode, and the fourth light emitting unit at least comprises a fourth anode; and the first anode is connected with the pixel drive circuit in the first circuit unit, the second anode is connected with the pixel drive circuit in the second circuit unit, the third anode is connected with the pixel drive circuit in the third circuit unit, and the fourth anode is connected with the pixel drive circuit in the fourth circuit unit;
wherein an orthographic projection of the first data signal line on the base substrate is at least partially overlapped with an orthographic projection of at least one of the second anode and the fourth anode on the base substrate, and/or, an orthographic projection of the third data signal line on the base substrate is at least partially overlapped with an orthographic projection of at least one of the second anode and the fourth anode on the base substrate.

20. The display substrate according to claim 13, wherein in a direction perpendicular to the base substrate, the drive structure layer comprises a plurality of conductive layers, the data trace portion, the first transfer electrode, and the second transfer electrode are disposed in a same conductive layer, and the second transfer electrode and the third transfer electrode are arranged in different conductive layers.
